(19) United States
(12) Patent Application Publication
(10) Pub. No.: US 2025/0015171 A1
(43) Pub. Date: Jan. 9, 2025

(54) SEMICONDUCTOR DEVICE

(71) Applicant: ROHM CO., LTD., Kyoto (JP)

(72) Inventors: Masaki AONO, Kyoto (JP); Atsushi NOCHIDA, Kyoto (JP)

(73) Assignee: ROHM CO., LTD., Kyoto (JP)

(21) Appl. No.: 18/895,465

(22) Filed: Sep. 25, 2024

Related U.S. Application Data
(63) Continuation of application No. PCT/JP2023/010676, filed on Mar. 17, 2023.

(30) Foreign Application Priority Data
Mar. 31, 2022 (JP) 2022-061084
Mar. 31, 2022 (JP) 2022-061085

(51) Int. Cl. H01L 29/739; H01L 27/07; H01L 29/06; H01L 29/10; H01L 29/16; H01L 29/861

(52) U.S. Cl. CPC H01L 29/7397; H01L 29/0615; H01L 29/0692; H01L 29/1095; H01L 27/0727; H01L 29/0657; H01L 29/1608; H01L 29/861

(57) ABSTRACT

The semiconductor device includes a chip which has a first surface on one side and a second surface on the other side, a plurality of IGBT regions which are provided at an interval in the chip, a boundary region which is provided in a region between the plurality of IGBT regions in the chip, a first conductivity type cathode region which is formed in a surface layer portion of the second surface in the boundary region, and a second conductivity type well region which is formed in a surface layer portion of the first surface in the boundary region.

### CROSS-REFERENCE TO RELATED APPLICATIONS

The present application is a bypass continuation of International Patent Application No. PCT/JP2023/010676 filed on Mar. 17, 2023, claiming the benefit of priority based on Japanese Patent Application No. 2022-061084 filed on Mar. 31, 2022, and Japanese Patent Application No. 2022-061085 filed on Mar. 31, 2022, and the entire disclosures of those applications are hereby incorporated herein by reference.

### BACKGROUND

### 1. Field of the Disclosure

The present disclosure relates to a semiconductor device.

### 2. Description of the Related Art

US2010/0090248A1 discloses a semiconductor device including an RC-IGBT (Reverse Conducting-Insulating Gate Bipolar Transistor).

### BRIEF DESCRIPTION OF THE DRAWINGS

FIG. 1 is a plan view which shows a semiconductor device according to a first embodiment.

FIG. 2 is a plan view which shows a layout example of a plurality of IGBT regions, a boundary region, a gate electrode and an emitter electrode.

FIG. 3 is a plan view which shows a layout example of a gate wiring, a boundary cathode region, a boundary well region, an outer well region and an outer cathode region.

FIG. 4 is an enlarged plan view which shows a layout example of the plurality of IGBT regions and the boundary region.

FIG. 5 is a cross-sectional view taken along line V-V shown in FIG. 4.

FIG. 6 is a cross-sectional view taken along line VI-VI shown in FIG. 4.

FIG. 7 is a cross-sectional view taken along line VII-VII shown in FIG. 4.

FIG. 8 is an enlarged plan view which shows a layout example of a peripheral edge portion of the IGBT region.

FIG. 9 is a cross-sectional view taken along line IX-IX shown in FIG. 8.

FIG. 10 is a cross-sectional view taken along line X-X shown in FIG. 8.

FIG. 11 is a cross-sectional view which shows a peripheral edge portion of a chip.

FIG. 12A is a plan view which shows another layout example of the cathode region.

FIG. 12B is a plan view which shows another layout example of the cathode region.

FIG. 12C is a plan view which shows another layout example of the cathode region.

FIG. 12D is a plan view which shows another layout example of the cathode region.

FIG. 12E is a plan view which shows another layout example of the cathode region.

FIG. 12F is a plan view which shows another layout example of the cathode region.

FIG. 12G is a plan view which shows another layout example of the cathode region.

FIG. 12H is a plan view which shows another layout example of the cathode region.

FIG. 12I is a plan view which shows another layout example of the cathode region.

FIG. 12J is a plan view which shows another layout example of the cathode region.

FIG. 12K is a plan view which shows another layout example of the cathode region.

FIG. 12L is a plan view which shows another layout example of the cathode region.

FIG. 12M is a plan view which shows another layout example of the cathode region.

FIG. 12N is a plan view which shows another layout example of the cathode region.

FIG. 13 is a plan view which shows a layout of a semiconductor device according to a reference example.

FIG. 14 is a graph which shows a relationship between a peak surge current and a forward voltage.

FIG. 15 is a plan view which shows a semiconductor device according to a second embodiment.

FIG. 16 is a plan view which shows a layout example of a plurality of IGBT regions, a boundary region, a gate electrode and an emitter electrode.

FIG. 17 is an enlarged plan view which shows a layout example of the plurality of IGBT regions and the boundary region.

FIG. 18 is a cross-sectional view taken along line XVIII-XVIII shown in FIG. 17.

FIG. 19 is a plan view which shows a semiconductor device according to a third embodiment.

FIG. 20 is a plan view which shows a layout example of a plurality of IGBT regions, a boundary region, a gate electrode and an emitter electrode.

FIG. 21 is an enlarged plan view which shows a layout example of the plurality of IGBT regions and the boundary region.

FIG. 22 is a cross-sectional view taken along line XXII-XXII shown in FIG. 21.

FIG. 23 is a plan view which shows a semiconductor device according to a fourth embodiment.

FIG. 24 is a plan view which shows a layout example of a plurality of IGBT regions, a boundary region, a gate electrode and an emitter electrode.

FIG. 25 is an enlarged plan view which shows a layout example of the plurality of IGBT regions and the boundary region.

FIG. 26 is a cross-sectional view which shows main parts of a semiconductor device according to a fifth embodiment.

FIG. 27 is a cross-sectional view which shows main parts of a semiconductor device according to a sixth embodiment.

FIG. 28 is a plan view which shows a modified example to be applied to each of the above-described embodiments.

FIG. 29 is a plan view which shows a modified example to be applied to each of the above-described embodiments.

FIG. 30 is a plan view which shows a modified example to be applied to each of the above-described embodiments.

### DETAILED DESCRIPTION OF THE PREFERRED EMBODIMENTS

Hereinafter, with reference to attached drawings, a detailed description will be given of the embodiments. The attached drawings are schematic drawings and not strictly illustrated, and scales, etc. are not necessarily in agreement. Also, corresponding structures in the attached drawings are given the same reference symbols and a redundant description will be omitted or simplified. A description made before omission or simplification will be given to a structure, the description of which has been omitted or simplified.

In a description which has a comparison target, where a wording of “substantially equal” is used, this wording includes not only the number (mode) equal to that of the comparison target but also includes a numerical error (mode error) in a range of ±10% based on the number (mode) of the comparison target. In each embodiment, wordings of “first,” “second,” “third,” etc., are used, and they are symbols which are given to a name of each structure for clarifying a description order and not given for the purpose of limiting the name of each structure.

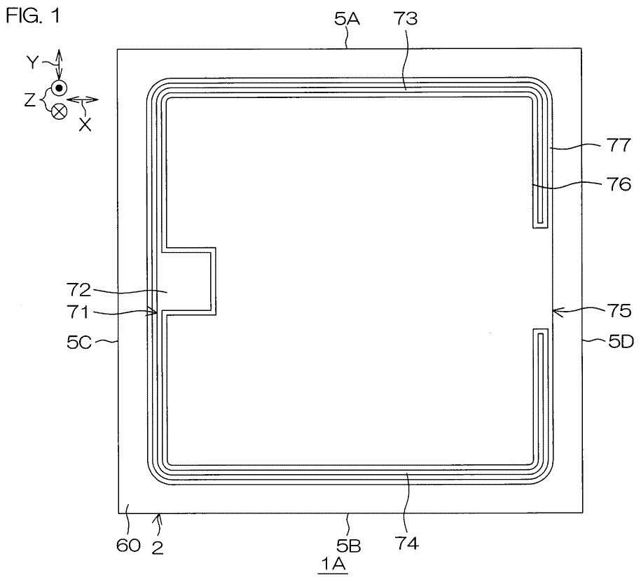

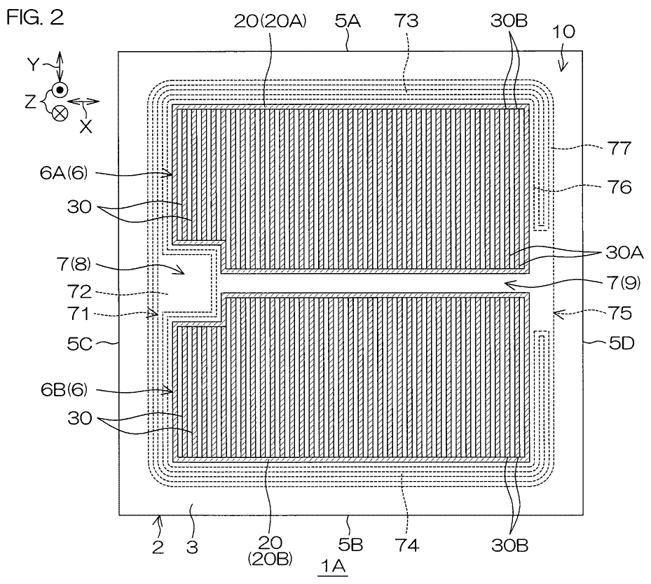

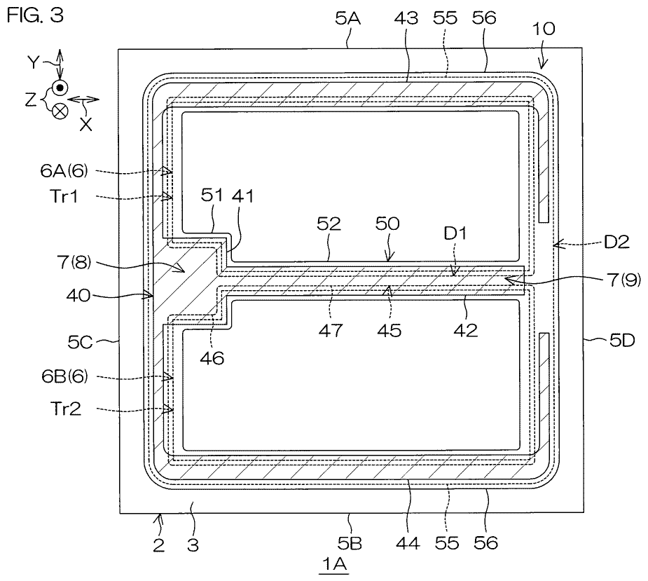

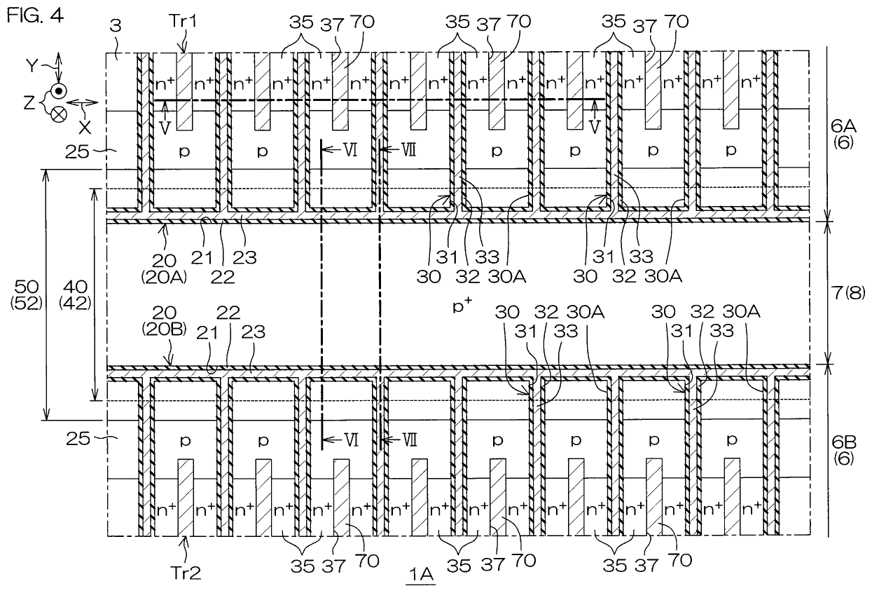

FIG. 1 is a plan view which shows a semiconductor device lA according to the first embodiment. FIG. 2 is a plan view which shows a layout example of a plurality of IGBT regions 6, a boundary region 7, a gate electrode 71 and an emitter electrode 75. FIG. 3 is a plan view which shows a layout example of a gate wiring 40, a boundary cathode region 45, a boundary well region 50, an outer cathode region 55 and an outer well region 56. FIG. 4 is an enlarged plan view of the layout example of the plurality of IGBT regions 6 and the boundary region 7.

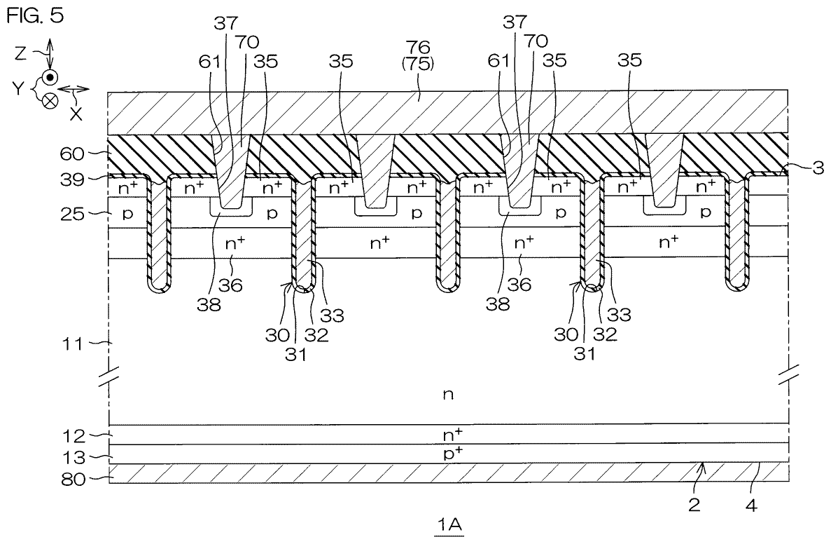

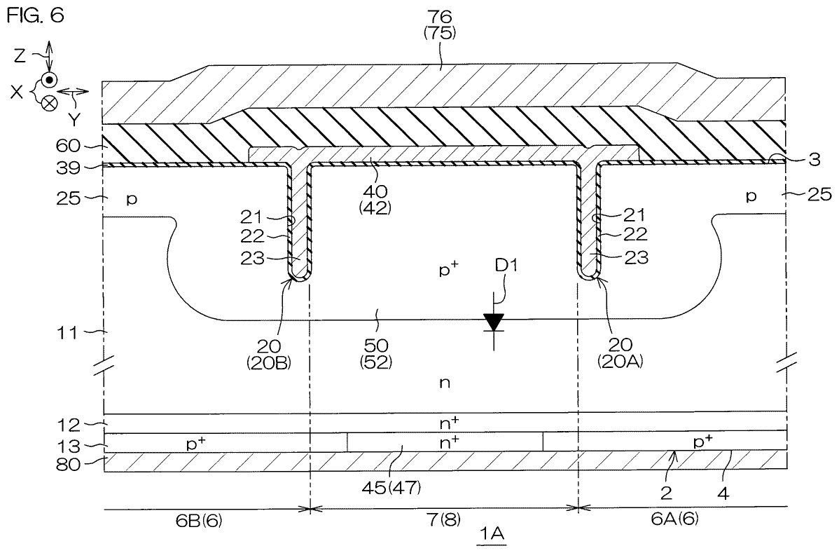

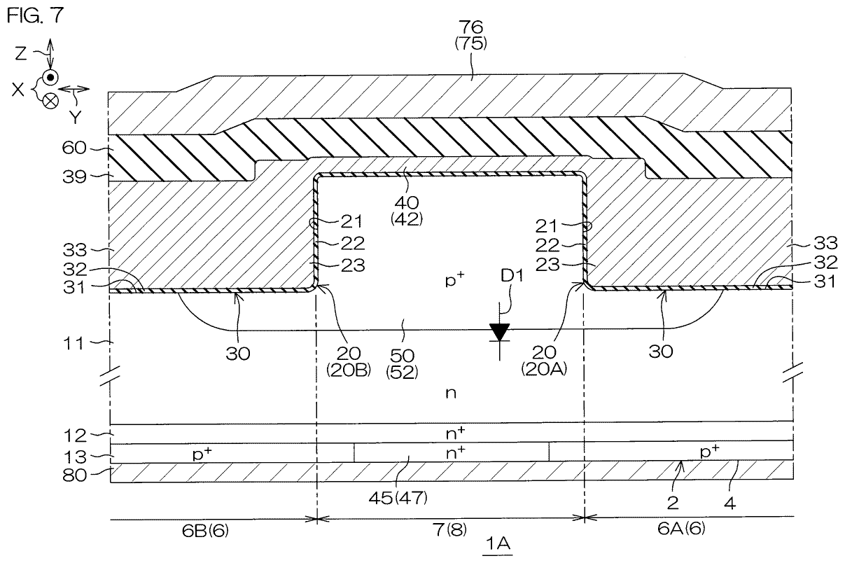

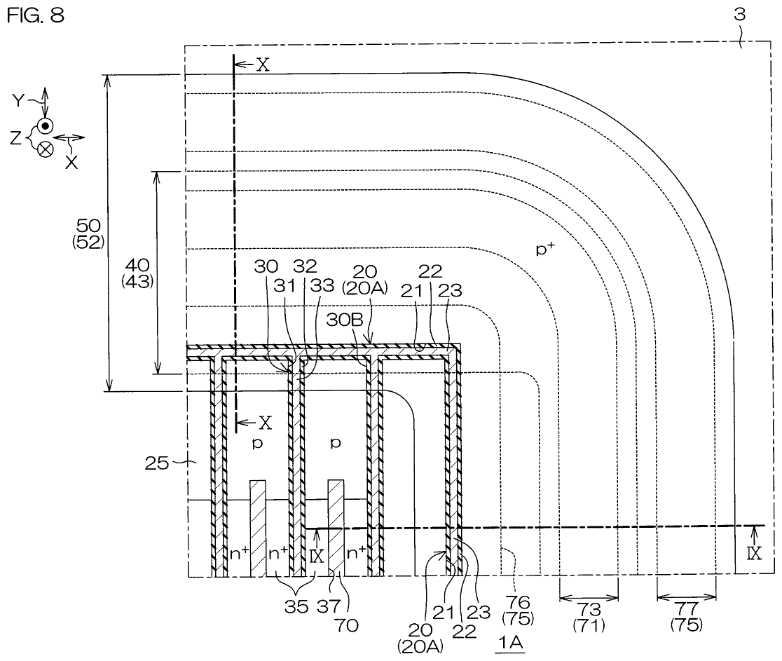

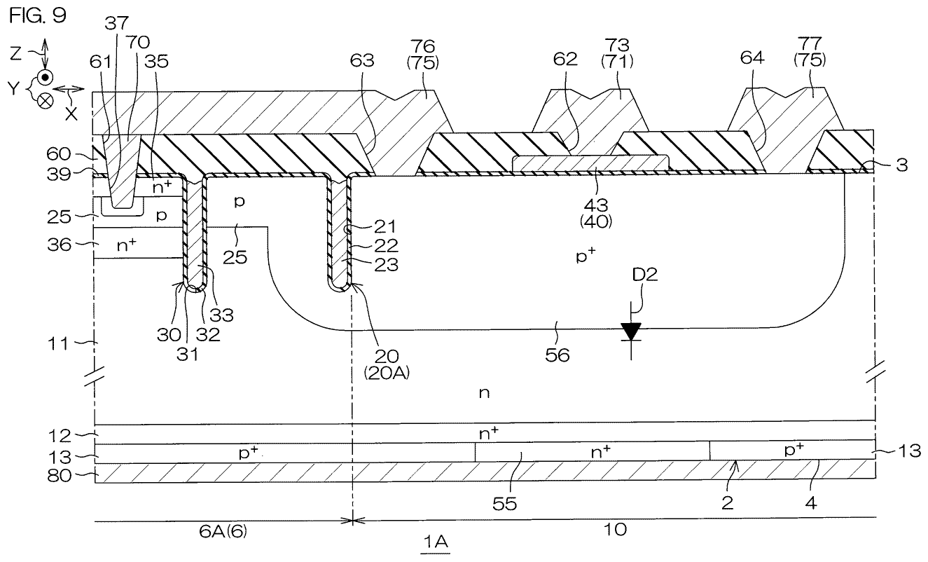

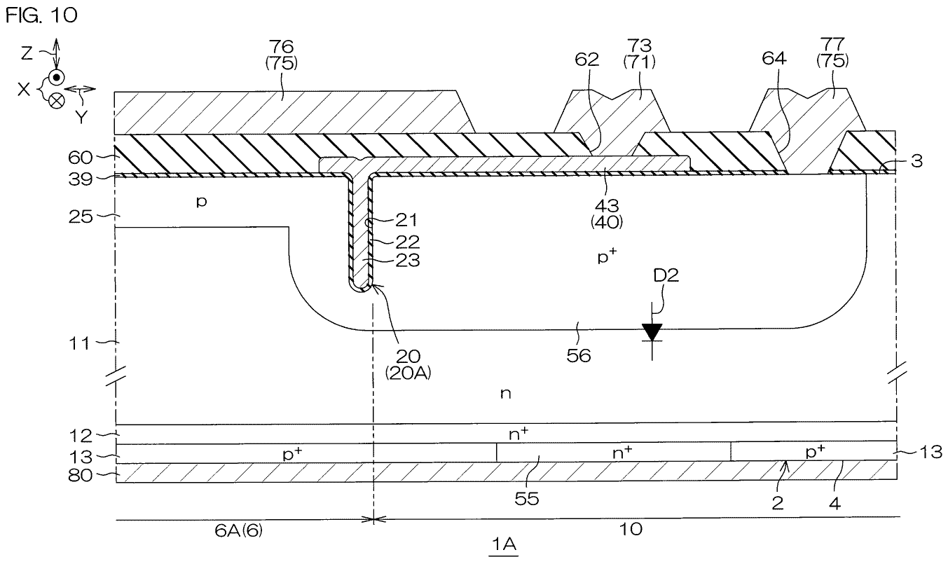

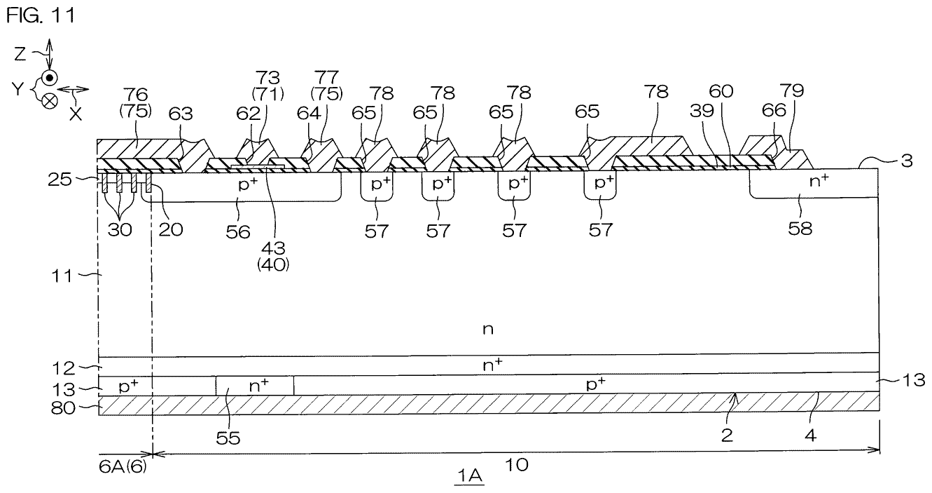

FIG. 5 is a cross-sectional view taken along line V-V shown in FIG. 4. FIG. 6 is a cross-sectional view taken along line VI-VI shown in FIG. 4. FIG. 7 is a cross-sectional view taken along line VII-VII shown in FIG. 4. FIG. 8 is an enlarged plan view which shows a layout example of a peripheral edge portion of the IGBT region 6. FIG. 9 is a cross-sectional view taken along line IX-IX shown in FIG. 8. FIG. 10 is a cross-sectional view taken along line X-X shown in FIG. 8. FIG. 11 is a cross-sectional view which shows a peripheral edge portion of a chip 2.

With reference to FIG. 1 to FIG. 11, the semiconductor device lA is an RC-IGBT semiconductor device (semiconductor switching device) having an RC-IGBT (Reverse Conducting-IGBT) which includes an IGBT (Insulated Gate Bipolar Transistor) and a diode in an integral manner. The diode is a reflux diode for the IGBT.

The semiconductor device lA includes the chip 2 which is formed in a hexahedron shape (specifically, a rectangular parallelepiped shape). The chip 2 may be referred to as a “semiconductor chip.” In this embodiment, the chip 2 has a single-layer structure consisting of a silicon monocrystal substrate (semiconductor substrate). The chip 2 has a first main surface 3 on one side, a second main surface 4 on the other side, and first to fourth side surfaces 5A to 5D which connect the first main surface 3 and the second main surface 4.

The first main surface 3 and the second main surface 4 are formed in quadrangular shapes in a plan view as viewed from a normal direction Z to them (which is simply referred to as a “plan view”). The normal direction Z is also a thickness direction of the chip 2. The first side surface 5A and the second side surface 5B extend in a first direction X along the first main surface 3 and face each other in a second direction Y intersecting the first direction X (specifically, orthogonal thereto). The third side surface 5C and the fourth side surface 5D extend in the second direction Y and face each other in the first direction X.

The semiconductor device 1A includes the plurality of IGBT regions 6 which are provided at an interval in the chip 2. Each of the IGBT regions 6 is a region which has an IGBT structure and may be referred to as an “active region.” The plurality of IGBT regions 6 include a first IGBT region 6A and a second IGBT region 6B.

The first IGBT region 6A is provided in a region at the first side surfaces 5A side in relation to a straight line which crosses a center of the first main surface 3 in the first direction X. The second IGBT region 6B is provided in a region at the second side surfaces 5B side in relation to a straight line which crosses the center of the first main surface 3 in the first direction X. In this embodiment, the plurality of IGBT regions 6 are each formed in a polygonal shape which has four sides parallel to the first to fourth side surfaces 5A to 5D in a plan view.

The semiconductor device 1A includes the boundary region 7 which is provided in a region between the plurality of IGBT regions 6. Specifically, the boundary region 7 is provided in a band shape extending in the first direction X in a region between the first IGBT region 6A and the second IGBT region 6B. In this embodiment, the boundary region 7 is positioned on the straight line which crosses the center of the first main surface 3 in the first direction X.

The boundary region 7 includes a first region 8 which has a relatively large first width in the second direction Y and a second region 9 which has a second width smaller than the first width in the second direction Y. The first region 8 is provided in a region on one side (third side surfaces 5C side) in the first direction X as a portion for supporting a terminal electrode. The first region 8 may be referred to as a “pad region,” a “wide region” or a “terminal supporting region.”

In this embodiment, the first region 8 is positioned on the straight line which crosses the center of the first main surface 3 in the first direction X in a plan view and provided in a quadrangular shape near a central portion of the third side surfaces 5C. The first width of the first region 8 may be not less than 100 μm and not more than 800 μm. The first width is preferably not less than 200 μm and not more than 600 μm. In this embodiment, the first width is set in a range of not less than 350 μm and not more than 450 μm.

The second region 9 is provided in a region on the other side (fourth side surface 5D side) in the first direction X in relation to the first region 8 as a portion for supporting wiring. The second region 9 is positioned on the straight line which crosses the center of the first main surface 3 in the first direction X and led out in a band shape from the first region 8 toward a central portion of the fourth side surfaces 5D. The second region 9 may be referred to as a “street region,” a “narrow region” or a “wiring supporting region.”

The second width of the second region 9 may be not less than 0.1 μm and not more than 500 μm. The second width is preferably not more than 100 μm. The second width may be set at a value falling under any range of not less than 0.1 μm and not more than 0.5 μm, not less than 0.5 μm and not more than 1 μm, not less than 1 μm and not more than 5 μm, not less than 5 μm and not more than 10 μm, not less than 10 μm and not more than 25 μm, not less than 25 μm and not more than 50 μm, not less than 50 μm and not more than 75 μm, or not less than 75 μm and not more than 100 μm.

The semiconductor device 1A includes an outer peripheral region 10 which is provided at a peripheral edge portion of the chip 2 such as to collectively surround the plurality of IGBT regions 6. The outer peripheral region 10 is provided in an annular shape (quadrangular annular shape) extending along the first to fourth side surfaces 5A to 5D.

The semiconductor device 1A includes an n-type (first conductivity type) drift region 11 which is formed inside the chip 2. The drift region 11 is formed in an entire area inside the chip 2. In this embodiment, the chip 2 is made of an n-type semiconductor substrate (n-type semiconductor chip), and the drift region 11 is formed by using the chip 2.

The semiconductor device 1A includes an n-type buffer region 12 which is formed in a surface layer portion of the second main surface 4. In this embodiment, the buffer region 12 is formed in a layer shape extending along the second main surface 4 in an entire area of the second main surface 4. The buffer region 12 has an n-type impurity concentration higher than that of the drift region 11. The presence or absence of the buffer region 12 is optional, and a configuration without the buffer region 12 may be adopted.

The semiconductor device 1A includes a p-type (second conductivity type) collector region 13 which is formed in the surface layer portion of the second main surface 4. In this embodiment, the collector region 13 is formed in a surface layer portion of the buffer region 12 on the second main surface 4 side. In this embodiment, the collector region 13 is formed in a layer shape extending along the second main surface 4 in an entire area of the second main surface 4. The collector region 13 is exposed from the second main surface 4 and s part of the first to fourth side surfaces 5A to 5D.

The semiconductor device 1A includes a plurality of trench separation structures 20 formed in the first main surface 3 so as to define the plurality of IGBT regions 6. A gate potential is to be applied to the plurality of trench separation structures 20. The trench separation structure 20 may be referred to as a “trench gate separating structure” or a “trench gate connecting structure.” The plurality of trench separation structures 20 include a first trench separation structure 20A which defines the first IGBT region 6A and a second trench separation structure 20B which defines the second IGBT region 6B.

The first trench separation structure 20A surrounds the first IGBT region 6A and defines the first IGBT region 6A from the boundary region 7 and the outer peripheral region 10. In this embodiment, the first trench separation structure 20A is formed in a polygonal annular shape having four sides parallel to the first to fourth side surfaces 5A to 5D in a plan view.

The second trench separation structure 20B surrounds the second IGBT region 6B and defines the second IGBT region 6B from the boundary region 7 and the outer peripheral region 10. In this embodiment, the second trench separation structure 20B is formed in a polygonal annular shape having four sides parallel to the first to fourth side surfaces 5A to 5D in a plan view.

The plurality of trench separation structures 20 each have a portion which is curved so as to define the first region 8 and the second region 9 of the boundary region 7 in a plan view. Each of the trench separation structures 20 preferably has a width which is less than a width of the second region 9 of the boundary region 7.

The width of each of the trench separation structures 20 may be not less than 0.5 μm and not more than 5 μm. The width of each of the trench separation structures 20 is preferably not less than 1 μm and not more than 2.5 μm. Each of the trench separation structures 20 may have a depth of not less than 1 μm and not more than 20 μm. The depth of each of the trench separation structures 20 is preferably not less than 4 μm and not more than 10 μm.

Hereinafter, description will be given of a configuration of one trench separation structure 20. The trench separation structure 20 includes a separation trench 21, a separation insulation film 22 and a separation buried electrode 23. The separation trench 21 digs down from the first main surface 3 toward the second main surface 4 and defines a wall surface of the trench separation structure 20.

The separation insulation film 22 is formed in a film shape along a wall surface of the separation trench 21 and defines a recess space inside the separation trench 21. The separation insulation film 22 may include at least one among a silicon oxide film, a silicon nitride film, a silicon oxynitride film and an aluminum oxide film. The separation insulation film 22 preferably has a single-layer structure made of a single insulation film. It is particularly preferable that the separation insulation film 22 includes a silicon oxide film made of an oxide of the chip 2.

The separation buried electrode 23 is buried in the separation trench 21 across the separation insulation film 22. In this embodiment, the separation buried electrode 23 is made of conductive polysilicon. A gate potential is to be applied to the separation buried electrode 23.

Hereinafter, description will be given of a structure inside the plurality of IGBT regions 6. The structure on the second IGBT region 6B side is substantially the same as the structure on the first IGBT region 6A side. Specifically, the structure on the second IGBT region 6B side is linearly symmetrical with the structure on the first IGBT region 6A side in relation to the boundary region 7. Hereinafter, description will be given of the structure on the first IGBT region 6A side. The structure on the second IGBT region 6B side will be described in accordance with the description of the structure on the first IGBT region 6A side, with a description thereof being omitted.

The semiconductor device 1A includes a p-type base region 25 which is formed in a surface layer portion of the first main surface 3 in the first IGBT region 6A. The base region 25 may be referred to as a “body region” or a “channel region.” The base region 25 is formed in a depth position shallower than the trench separation structure 20 and has a bottom portion which is positioned further on the first main surface 3 side than a bottom wall of the trench separation structure 20. The base region 25 extends in a layer shape along the first main surface 3 and is connected to an inner peripheral wall of the trench separation structure 20.

The semiconductor device 1A includes a plurality of trench structures 30 which are formed in the first main surface 3 in the first IGBT region 6A. A gate potential is to be applied to the plurality of trench structures 30. The trench structure 30 may be referred to as a “trench gate structure.” The plurality of trench structures 30 penetrate through the base region 25 so as to reach the drift region 11. The plurality of trench structures 30 are arrayed at an interval in the first direction X in a plan view and each formed in a band shape extending in the second direction Y. That is, the plurality of trench structures 30 are arrayed in a stripe extending in the second direction Y.

The plurality of trench structures 30 each have a first end 30A on the boundary region 7 side and a second end 30B on the outer peripheral region 10 side with regard to a longitudinal direction (second direction Y). The first end 30A and the second end 30B are mechanically and electrically connected to the trench separation structure 20. That is, the plurality of trench structures 30 constitute one ladder-shaped trench gate structure together with the trench separation structure 20. A portion at which the trench structure 30 and the trench separation structure 20 are connected may be regarded as a part of the trench separation structure 20 or may be regarded as a part of the trench structure 30.

The plurality of trench structures 30 may be arrayed at an interval of not less than 0.5 μm and not more than 5 μm in the first direction X. The interval between the plurality of trench structures 30 is preferably not less than 1 μm and not more than 3 μm. The interval between the plurality of trench structures 30 is preferably less than the width of the second region 9 of the boundary region 7.

Each of the trench structures 30 may have a width which is not less than 0.5 μm and not more than 5 μm. The width of each of the trench structures 30 is a width in a direction orthogonal to a direction at which each of the trench structures 30 extends. The width of each of the trench structures 30 is preferably not less than 1 μm and not more than 2.5 μm. The width of each of the trench structures 30 is preferably less than the width of the second region 9 of the boundary region 7. It is preferable that the width of each of the trench structures 30 is substantially equal to a width of the trench separation structure 20.

Each of the trench structures 30 may have a depth which is not less than 1 μm and not more than 20 μm. The depth of each of the trench structures 30 is preferably not less than 4 μm and not more than 10 μm. It is preferable that the depth of each of the trench structures 30 is substantially equal to a depth of the trench separation structure 20.

Hereinafter, description will be given of a configuration of one trench structure 30. The trench structure 30 includes a gate trench 31, a gate insulation film 32 and a gate buried electrode 33. The gate trench 31 digs down from the first main surface 3 toward the second main surface 4 and defines a wall surface of the trench structure 30. In this embodiment, the gate trench 31 communicates with the separation trench 21 at both ends (first end 30A and second end 30B) in the second direction Y. Specifically, a side wall of the gate trench 31 communicates with a side wall of the separation trench 21, and a bottom wall of the gate trench 31 communicates with a bottom wall of the separation trench 21.

The gate insulation film 32 is formed in a film shape along a wall surface of the gate trench 31 and defines a recess space inside the gate trench 31. The gate insulation film 32 may include at least one among a silicon oxide film, a silicon nitride film, a silicon oxynitride film and an aluminum oxide film.

The gate insulation film 32 preferably has a single-layer structure which is made of a single insulation film. It is particularly preferable that the gate insulation film 32 includes a silicon oxide film made of an oxide of the chip 2. In this embodiment, the gate insulation film 32 is made of the same insulation film as the separation insulation film 22. The gate insulation film 32 is connected to the separation insulation film 22 at a communication portion of the separation trench 21 and the gate trench 31.

The gate buried electrode 33 is buried in the gate trench 31 across the gate insulation film 32. In this embodiment, the gate buried electrode 33 is made of conductive polysilicon. A gate potential is to be applied to the gate buried electrode 33. The gate buried electrode 33 is connected to the separation buried electrode 23 at the communication portion of the separation trench 21 and the gate trench 31.

The semiconductor device 1A includes a plurality of n-type emitter regions 35 which are formed in a surface layer portion of the base region 25. The plurality of emitter regions 35 are arranged at both sides of the plurality of trench structures 30 and each formed in a band shape extending along the plurality of trench structures 30 in a plan view. The plurality of emitter regions 35 each have an n-type impurity concentration higher than that of the drift region 11.

The semiconductor device 1A includes a plurality of n-type carrier storage regions 36 which are formed in a region directly below the base region 25 inside the chip 2. The plurality of carrier storage regions 36 prevent carriers (holes) from being discharged to the base region 25 and facilitate accumulation of the carriers (holes) in a region directly below the plurality of trench structures 30. That is, the plurality of carrier storage regions 36 facilitate attaining a low on-resistance and a low on-voltage from the inside of the chip 2.

The plurality of carrier storage regions 36 are arranged at both sides of the plurality of trench structures 30 and each formed in a band shape extending along the plurality of trench structures 30 in a plan view. The plurality of carrier storage regions 36 are each formed in a region between a bottom portion of the base region 25 and a bottom wall of the trench structure 30 with regard to the thickness direction of the chip 2. The plurality of carrier storage regions 36 are preferably separated from the bottom wall of the trench structure 30 to the base region 25 side.

Bottom portions of the plurality of carrier storage regions 36 are preferably positioned further on the bottom wall side of the trench structure 30 than an intermediate portion of the trench structure 30. The plurality of carrier storage regions 36 have an n-type impurity concentration higher than that of the drift region 11. The plurality of carrier storage regions 36 are preferably lower in n-type impurity concentration than the emitter region 35. The presence or absence of the carrier storage region 36 is optional. Therefore, a configuration without the carrier storage region 36 may be adopted.

The semiconductor device 1A includes a plurality of contact holes 37 which are formed in the first main surface 3 so as to expose the emitter region 35. The plurality of contact holes 37 are formed in both sides of the plurality of trench structures 30 at an interval from the plurality of trench structures 30 in the first direction X. The plurality of contact holes 37 may be each formed in a tapered shape in which an opening width is narrowed from an opening toward a bottom wall.

The plurality of contact holes 37 may be separated from a bottom portion of the emitter region 35 to the first main surface 3 side so as not to reach the base region 25. As a matter of course, the plurality of contact holes 37 may penetrate through the emitter region 35 so as to reach the base region 25. The plurality of contact holes 37 are each formed in a band shape extending along the plurality of trench structures 30 in a plan view. With regard to the longitudinal direction (second direction Y), the plurality of contact holes 37 are shorter than the plurality of trench structures 30.

The semiconductor device 1A includes a plurality of p-type contact regions 38 which are formed in a region different from the plurality of emitter regions 35 in the surface layer portion of the base region 25. The plurality of contact regions 38 are each formed in a band shape extending along a corresponding contact hole 37 in a plan view. Bottom portions of the plurality of contact regions 38 are each formed in a region between a bottom wall of the corresponding contact hole 37 and the bottom portion of the base region 25. The plurality of contact regions 38 have a p-type impurity concentration higher than that of the base region 25.

As described so far, the first IGBT region 6A includes the base region 25, the plurality of trench structures 30, the plurality of emitter regions 35, the plurality of carrier storage regions 36, the plurality of contact holes 37 and the plurality of contact regions 38. As with the first IGBT region 6A, the second IGBT region 6B includes the base region 25, the plurality of trench structures 30, the plurality of emitter regions 35, the plurality of carrier storage regions 36, the plurality of contact holes 37 and the plurality of contact regions 38.

The semiconductor device 1A includes a main surface insulation film 39 which covers the first main surface 3. The main surface insulation film 39 may include at least one among a silicon oxide film, a silicon nitride film, a silicon oxynitride film and an aluminum oxide film. The main surface insulation film 39 preferably has a single-layer structure which is made of a single insulation film. It is particularly preferable that the main surface insulation film 39 incudes a silicon oxide film which is made of an oxide of the chip 2. In this embodiment, the main surface insulation film 39 is made of the same insulation film as the gate insulation film 32.

The main surface insulation film 39 extends in a film shape along the first main surface 3 such as to cover the plurality of IGBT regions 6, the boundary region 7 and the outer peripheral region 10. The main surface insulation film 39 may continue to the peripheral edge (first to fourth side surfaces 5A to 5D) of the chip 2. The main surface insulation film 39 covers the first main surface 3 such as to expose the plurality of trench separation structures 20 and the plurality of trench structures 30. Specifically, the main surface insulation film 39 is connected to the separation insulation film 22 and the gate insulation film 32 and exposes the separation buried electrode 23 and the gate buried electrode 33.

The semiconductor device 1A includes the gate wiring 40 which is arranged above (anywhere above) the first main surface 3. Specifically, the gate wiring 40 is arranged on (anywhere on) the main surface insulation film 39 in a film shape. In this embodiment, the gate wiring 40 is made of a conductive polysilicon film. The gate wiring 40 is routed around at least into the boundary region 7. In this embodiment, the gate wiring 40 is routed around into the boundary region 7 and the outer peripheral region 10 in an arbitrary layout.

Specifically, the gate wiring 40 includes a pad wiring 41, a boundary wiring 42, a first outer wiring 43 and a second outer wiring 44. The pad wiring 41 is arranged above the first region 8 of the boundary region 7 and has a relatively large first wiring width in the second direction Y. In this embodiment, the pad wiring 41 is formed in a quadrangular shape in a plan view. The pad wiring 41 has a width larger than a width of the boundary region 7 (first width of the first region 8) in the second direction Y. The pad wiring 41 is led out above the plurality of trench separation structures 20 which are adjacent to each other from above the boundary region 7 in the second direction Y.

In this embodiment, the pad wiring 41 is led out above the plurality of IGBT regions 6 from above the boundary region 7 so as to cover the first ends 30A of the plurality of trench structures 30. Thereby, the pad wiring 41 is mechanically and electrically connected to the separation buried electrode 23 and a plurality of gate buried electrodes 33 and transmits a gate potential to the separation buried electrode 23 and the gate buried electrode 33. In this embodiment, the pad wiring 41 is formed integrally with the separation buried electrode 23 and the plurality of gate buried electrodes 33.

The boundary wiring 42 is led out above the second region 9 of the boundary region 7 from the pad wiring 41 and has a second wiring width smaller than the first wiring width of the pad wiring 41 in the second direction Y. The boundary wiring 42 is formed in a band shape extending in the first direction X. In this embodiment, the boundary wiring 42 crosses a center of the chip 2. The boundary wiring 42 has a width larger than the width of the boundary region 7 (second width of the second region 9) in the second direction Y. The boundary wiring 42 is led out above the plurality of trench separation structures 20 which are adjacent to each other from above the boundary region 7 in the second direction Y.

In this embodiment, the boundary wiring 42 is led out above the plurality of IGBT regions 6 from above the boundary region 7 such as to cover the first ends 30A of the plurality of trench structures 30. Thereby, the boundary wiring 42 is mechanically and electrically connected to the separation buried electrode 23 and the plurality of gate buried electrodes 33 and transmits a gate potential to the separation buried electrode 23 and the gate buried electrode 33. In this embodiment, the boundary wiring 42 is formed integrally with the separation buried electrode 23 and the plurality of gate buried electrodes 33.

The first outer wiring 43 is led out above the outer peripheral region 10 from the pad wiring 41 and formed in a band shape extending along the first side surface 5A and the third side surface 5C. The first outer wiring 43 may have a portion which extends in a band shape along the fourth side surface 5D. The first outer wiring 43 has a portion which is led out above the first trench separation structure 20A from above the outer peripheral region 10 at a portion which extends along the first side surface 5A. In this embodiment, the first outer wiring 43 also covers the second ends 30B of the plurality of trench structures 30 in the first IGBT region 6A.

Thereby, the first outer wiring 43 is mechanically and electrically connected to the separation buried electrode 23 and the plurality of gate buried electrodes 33. In this embodiment, the first outer wiring 43 is formed integrally with the separation buried electrode 23 and the plurality of gate buried electrodes 33. The first outer wiring 43 transmits a gate potential from the outer peripheral region 10 side to the separation buried electrode 23 and the gate buried electrode 33.

The second outer wiring 44 is led out above the outer peripheral region 10 from the pad wiring 41 and formed in a band shape extending along the second side surface 5B and the third side surface 5C. The second outer wiring 44 may have a portion which extends in a band shape along the fourth side surface 5D. The second outer wiring 44 has a portion which is led out above the second trench separation structure 20B from above the outer peripheral region 10 at a portion which extends along the second side surface 5B. In this embodiment, the second outer wiring 44 also covers the second ends 30B of the plurality of trench structures 30 in the second IGBT region 6B.

Thereby, the second outer wiring 44 is mechanically and electrically connected to the separation buried electrode 23 and the plurality of gate buried electrodes 33. In this embodiment, the second outer wiring 44 is formed integrally with the separation buried electrode 23 and the plurality of gate buried electrodes 33. The second outer wiring 44 transmits a gate potential from the outer peripheral region 10 side to the separation buried electrode 23 and the gate buried electrode 33.

With reference to FIG. 3 and FIG. 6, the semiconductor device 1A includes the n-type boundary cathode region 45 which is formed in the surface layer portion of the second main surface 4 in the boundary region 7. The boundary cathode region 45 is formed in a layer shape extending along the second main surface 4. The boundary cathode region 45 penetrates through the collector region 13 so as to be connected to the buffer region 12 and is exposed from the second main surface 4.

The boundary cathode region 45 is made of a region which has an n-type impurity concentration higher than a p-type impurity concentration of the collector region 13 and in which the conductivity type of the collector region 13 is replaced partially from a p-type to an n-type. The boundary cathode region 45 preferably has an n-type impurity concentration higher than that of the drift region 11 (buffer region 12).

The boundary cathode region 45 is formed in a region held between the first trench separation structure 20A and the second trench separation structure 20B in a plan view. That is, the boundary cathode region 45 is formed in a region held between the plurality of trench structures 30 on the first IGBT region 6A side and the plurality of trench structures 30 on the second IGBT region 6B side in a plan view. The boundary cathode region 45 is preferably formed at an interval from the base region 25 of each of the IGBT regions 6 in a direction along the second main surface 4 (second direction Y) such as not to face the base region 25 of each of the IGBT regions 6 in the thickness direction of the chip 2.

It is particularly preferable that the boundary cathode region 45 is formed at an interval from the plurality of trench structures 30 in a direction along the second main surface 4 (second direction Y) such as not to face the plurality of trench structures 30 in the thickness direction of the chip 2. In this embodiment, the boundary cathode region 45 is formed at an interval from the plurality of trench separation structures 20 in a direction along the second main surface 4 (second direction Y) such as not to face the plurality of trench separation structures 20 in the thickness direction of the chip 2.

That is, the boundary cathode region 45 has a width smaller than the width of the boundary region 7 in the second direction Y. Also, the boundary cathode region 45 is formed only in the boundary region 7 and not formed in the plurality of IGBT regions 6. Also, the boundary cathode region 45 is formed in the surface layer portion of the second main surface 4 such that the collector region 13 may partially remain in the boundary region 7. That is, the semiconductor device 1A includes the collector region 13 which is formed in the boundary region 7.

In this embodiment, the boundary cathode region 45 has a width smaller than a width of the gate wiring 40 (boundary wiring 42) in the second direction Y in a plan view and has a peripheral edge portion which is positioned further inside than a peripheral edge portion of the gate wiring 40. That is, an entire area of the boundary cathode region 45 faces the gate wiring 40 in the thickness direction of the chip 2 in a cross-sectional view. As a matter of course, the boundary cathode region 45 may have a width larger than the width of the gate wiring 40 in a plan view and may have a peripheral edge portion that is positioned further outside than the peripheral edge portion of the gate wiring 40.

The boundary cathode region 45 is formed in a band shape extending along the boundary region 7 in a plan view. That is, the boundary cathode region 45 extends along a direction in which the plurality of trench structures 30 are arrayed. The boundary cathode region 45 faces the gate wiring 40 in the thickness direction of the chip 2. Specifically, the boundary cathode region 45 faces the pad wiring 41 and the boundary wiring 42 in the thickness direction of the chip 2.

More specifically, the boundary cathode region 45 includes a first cathode region 46 that is formed in the first region 8 of the boundary region 7 and a second cathode region 47 that is formed in the second region 9 of the boundary region 7. The first cathode region 46 has a relatively large first cathode width in the second direction Y and faces the pad wiring 41 in the thickness direction of the chip 2. In this embodiment, the first cathode region 46 is formed in a quadrangular shape in a plan view.

The first cathode region 46 preferably has a first cathode width which is not more than the first wiring width of the pad wiring 41 (more preferably, less than the first wiring width). In this embodiment, the first cathode region 46 has a first cathode width which is not more than the first width of the first region 8 of the boundary region 7 (specifically, less than the first width). That is, the first cathode region 46 has a plane area which is not more than a plane area of the first region 8 (specifically, less than the plane area of the first region 8). The first cathode region 46 preferably has a first cathode width which is not less than 1/10 of the first width.

The second cathode region 47 has a second cathode width smaller than the first cathode width of the first cathode region 46 in the second direction Y and is led out in a band shape from the first cathode region 46 toward the second region 9 of the boundary region 7. The second cathode region 47 faces the boundary wiring 42 in the thickness direction of the chip 2.

In this embodiment, the second cathode region 47 is positioned on a straight line which crosses the center of the first main surface 3 in the first direction X. Specifically, the second cathode region 47 extends in a band shape so as to be positioned in a region on one side (third side surfaces 5C side) and in a region on the other side (fourth side surfaces 5D side) in the first direction X in relation to a straight line which crosses the center of the first main surface 3 in the second direction Y.

The second cathode region 47 preferably has a second cathode width which is not more than the second wiring width of the boundary wiring 42 (more preferably, less than the second wiring width). In this embodiment, the second cathode region 47 has a second cathode width which is not more than the second width of the second region 9 of the boundary region 7 (specifically, less than the second width). That is, the second cathode region 47 has a plane area which is not more than a plane area of the second region 9 (specifically, less than the plane area of the second region 9). The second cathode region 47 preferably has a second cathode width which is not less than 1/10 of the second width.

The semiconductor device 1A includes the p-type boundary well region 50 which is formed in the surface layer portion of the first main surface 3 in the boundary region 7. The boundary well region 50 may be referred to as a “boundary anode region.” In this embodiment, the boundary well region 50 has a p-type impurity concentration higher than that of the plurality of base regions 25. As a matter of course, the boundary well region 50 may have a p-type impurity concentration lower than that of the plurality of base regions 25.

The boundary well region 50 is formed in a layer shape extending along the first main surface 3 and exposed from the first main surface 3. The boundary well region 50 is formed in a region held between the first trench separation structure 20A and the second trench separation structure 20B. That is, the boundary well region 50 is formed in a region held between the plurality of trench structures 30 on the first IGBT region 6A side and the plurality of trench structures 30 on the second IGBT region 6B side.

The boundary well region 50 is formed deeper than the plurality of base regions 25 and connected to the plurality of trench separation structures 20. Specifically, the boundary well region 50 is formed deeper than the plurality of trench separation structures 20 (the plurality of trench structures 30) and has a portion which covers the bottom walls of the plurality of trench separation structures 20.

In this embodiment, the boundary well region 50 has a width larger than the width of the boundary region 7 in the second direction Y and is led out to the inside of each of the IGBT regions 6 from the boundary region 7. It is preferable that the boundary well region 50 has a width larger than the width of the gate wiring 40 in the second direction Y and has a peripheral edge portion which protrudes externally (internal portion side of each IGBT region 6) further than the peripheral edge portion of the gate wiring 40. The boundary well region 50 has a portion which crosses the plurality of trench separation structures 20 and covers the bottom walls of the plurality of trench structures 30.

The boundary well region 50 covers a side wall of the trench separation structure 20 and side walls of the plurality of trench structures 30 inside each of the IGBT regions 6 and is connected to each of the base regions 25 in the surface layer portion of the first main surface 3. The boundary well region 50 is electrically connected to the base region 25 and the emitter region 35 inside each of the IGBT regions 6. A depth of the boundary well region 50 may be not less than 1 μm and not more than 20 μm. The depth of the boundary well region 50 is preferably not less than 5 μm and not more than 10 μm.

The boundary well region 50 faces the boundary cathode region 45 in the thickness direction of the chip 2. Specifically, the boundary well region 50 has a width larger than the width of the boundary cathode region 45 in the second direction Y and has a portion (internal portion) which faces the boundary cathode region 45 in the thickness direction of the chip 2 and a portion (peripheral edge portion) which faces the collector region 13 in the thickness direction of the chip 2.

In this embodiment, the boundary well region 50 faces the collector region 13 and the boundary cathode region 45 at a portion positioned inside the boundary region 7 and faces the collector region 13 at a portion positioned inside each of the IGBT regions 6. That is, the boundary well region 50 has a portion which faces the collector region 13 in each of the IGBT regions 6 and the boundary region 7. The boundary well region 50 preferably faces an entire area of the boundary cathode region 45 in a cross-sectional view.

The boundary well region 50 is formed in a band shape extending along the boundary region 7 in a plan view. That is, the boundary well region 50 extends along a direction in which the plurality of trench structures 30 are arrayed. The boundary well region 50 faces the gate wiring 40 and the boundary cathode region 45 in the thickness direction of the chip 2. Specifically, the boundary well region 50 faces the pad wiring 41 and the boundary wiring 42 in the thickness direction of the chip 2 and faces the first cathode region 46 and the second cathode region 47 in the thickness direction of the chip 2.

More specifically, the boundary well region 50 includes a first well region 51 that is formed in the first region 8 of the boundary region 7 and a second well region 52 that is formed in the second region 9 of the boundary region 7. The first well region 51 has a relatively large first well width in the second direction Y and faces the pad wiring 41 and the first cathode region 46 in the thickness direction of the chip 2. In this embodiment, the first well region 51 is formed in a quadrangular shape in a plan view.

The first well region 51 preferably has a first well width which is not less than the first cathode width of the first cathode region 46 (more preferably, larger than the first cathode width). The first well region 51 preferably faces an entire area of the first cathode region 46 in the thickness direction of the chip 2 in a cross-sectional view. It is particularly preferable that the first well region 51 has a plane area which is not less than the plane area of the first cathode region 46 (more preferably, larger than the plane area of the first cathode region 46).

The first well region 51 preferably has a first well width which is not less than the first wiring width of the pad wiring 41 (more preferably, a first well width larger than the first wiring width). The first well region 51 preferably faces an entire arear of the pad wiring 41 in the thickness direction of the chip 2 in a cross-sectional view. It is particularly preferable that the first well region 51 has a plane area which is not less than the plane area of the pad wiring 41 (more preferably, larger than the plane area of the pad wiring 41).

It is particularly preferable that the first well region 51 has a first well width which is not less than the first width of the first region 8 of the boundary region 7 (more preferably, larger than the first width). It is particularly preferable that the first well region 51 has a plane area which is not less than the plane area of the first region 8 (more preferably, larger than the plane area of the first region 8). The first well width is preferably not more than two times the first width (more preferably, not more than 1.5 times the first width).

The second well region 52 is led out in a band shape from the first well region 51 toward the second region 9 of the boundary region 7 and has a second well width smaller than the first well width of the first well region 51 in the second direction Y. The second well region 52 faces the boundary wiring 42 and the second cathode region 47 in the thickness direction of the chip 2.

In this embodiment, the second well region 52 is positioned on a straight line which crosses the center of the first main surface 3 in the first direction X. Specifically, the second well region 52 extends in a band shape so as to be positioned in a region on one side (third side surface 5C side) and in a region on the other side (fourth side surface 5D side) in the first direction X in relation to a straight line which crosses the center of the first main surface 3 in the second direction Y.

The second well region 52 preferably has a second well width which is not less than the second cathode width of the second cathode region 47 (more preferably, larger than the second cathode width). The second well region 52 preferably faces an entire area of the second cathode region 47 in the thickness direction of the chip 2 in a cross-sectional view. It is particularly preferable that the second well region 52 has a plane area which is not less than the plane area of the second cathode region 47 (more preferably, larger than the plane area of the second cathode region 47).

The second well region 52 preferably has a second well width which is not less than the second wiring width of the boundary wiring 42 (more preferably, larger than the second wiring width). The second well region 52 preferably faces an entire area of the boundary wiring 42 in the thickness direction of the chip 2 in a cross-sectional view. It is particularly preferable that the second well region 52 has a plane area which is not less than the plane area of the boundary wiring 42 (more preferably, larger than the plane area of the boundary wiring 42).

It is particularly preferable that the second well region 52 has a second well width which is not less than the second width of the second region 9 of the boundary region 7 (more preferably, larger than the second width). It is particularly preferable that the second well region 52 has a plane area which is not less than the plane area of the second region 9 (more preferably, larger than the plane area of the second region 9). The second well width is preferably not more than two times the second width (more preferably, not more than 1.5 times the second width).

The semiconductor device 1A includes the n-type outer cathode region 55 that is formed in the surface layer portion of the second main surface 4 in the outer peripheral region 10. The outer cathode region 55 is formed in a layer shape extending along the second main surface 4. The outer cathode region 55 penetrates through the collector region 13 so as to be connected to the buffer region 12 and is exposed from the second main surface 4.

The outer cathode region 55 is a region which has an n-type impurity concentration higher than the p-type impurity concentration of the collector region 13 and in which the conductivity type of the collector region 13 is partially replaced from a p-type to an n-type. The outer cathode region 55 preferably has an n-type impurity concentration higher than that of the drift region 11 (buffer region 12). The n-type impurity concentration of the outer cathode region 55 is preferably substantially equal to the n-type impurity concentration of the boundary cathode region 45.

The outer cathode region 55 is formed at an interval inward from a peripheral edge (first to fourth side surfaces 5A to 5D) of the second main surface 4. The outer cathode region 55 is formed in a band shape extending along the plurality of IGBT regions 6 in a plan view. In this embodiment, the outer cathode region 55 is formed in an annular shape that surrounds the plurality of IGBT regions 6 in a plan view. Specifically, the outer cathode region 55 is formed in an annular shape (quadrangular annular shape) having four sides parallel to the peripheral edge of the second main surface 4.

The outer cathode region 55 is preferably formed in the peripheral edge side of the chip 2 at an interval from the base region 25 of each of the IGBT regions 6 at least such that it does not to face the base region 25 of each of the IGBT regions 6 in the thickness direction of the chip 2. The outer cathode region 55 is formed in the peripheral edge side of the chip 2 at an interval from the plurality of trench structures 30 such as not to face the plurality of trench structures 30 in the thickness direction of the chip 2.

It is particularly preferable that the outer cathode region 55 is formed in the peripheral edge side of the chip 2 at an interval from the plurality of trench separation structures 20 such as not to face the plurality of trench separation structures 20 in the thickness direction of the chip 2. That is, it is preferable that the outer cathode region 55 is formed only in the outer peripheral region 10 and not formed in the plurality of IGBT regions 6.

The outer cathode region 55 may be connected to the boundary cathode region 45 at a portion at which the boundary region 7 and the outer peripheral region 10 are connected. The outer cathode region 55 faces the first outer wiring 43 and the second outer wiring 44 of the gate wiring 40 in the thickness direction of the chip 2.

A ratio of the plane area of the cathode region to the plane area of the second main surface 4 is preferably not less than 0.1% and not more than 10%. The plane area of the cathode region is a total plane area of the plane area of the boundary cathode region 45 and the plane area of the outer cathode region 55. The ratio of the plane area of the cathode region may fall under any one of such ranges that are not less than 0.1% and not more than 1%, not less than 1% and not more than 2%, not less than 2% and not more than 4%, not less than 4% and not more than 6%, not less than 6% and not more than 8%, and not less than 8% and not more than 10%.

The semiconductor device 1A includes the p-type outer well region 56 which is formed in the surface layer portion of the first main surface 3 in the outer peripheral region 10. The outer well region 56 may be referred to as an “outer anode region.” In this embodiment, the outer well region 56 has a p-type impurity concentration higher than that of the plurality of base regions 25. As a matter of course, the outer well region 56 may have a p-type impurity concentration lower than that of the plurality of base regions 25. The p-type impurity concentration of the outer well region 56 is preferably substantially equal to the p-type impurity concentration of the boundary well region 50.

The outer well region 56 is formed in a layer shape extending along the first main surface 3 and exposed from the first main surface 3. The outer well region 56 is formed at an interval inward from the peripheral edge (first to fourth side surfaces 5A to 5D) of the first main surface 3. The outer well region 56 is formed in a band shape extending along the plurality of IGBT regions 6 in a plan view. In this embodiment, the outer well region 56 is formed in an annular shape that surrounds the plurality of IGBT regions 6 in a plan view. Specifically, the outer well region 56 is formed in an annular shape (quadrangular annular shape) having four sides parallel to the peripheral edge of the first main surface 3.

The outer well region 56 is formed deeper than the plurality of base regions 25. Specifically, the outer well region 56 is formed deeper than the plurality of trench separation structures 20 (the plurality of trench structures 30). In this embodiment, the outer well region 56 has a depth substantially equal to that of the boundary well region 50.

The outer well region 56 is connected to the plurality of trench separation structures 20. The outer well region 56 has a portion which covers the bottom walls of the plurality of trench separation structures 20. The outer well region 56 is led out to the inside of each of the IGBT regions 6 from the outer peripheral region 10. The outer well region 56 has a portion which crosses the plurality of trench separation structures 20 and covers the bottom walls of the plurality of trench structures 30.

The outer well region 56 covers a side wall of the trench separation structure 20 and side walls of the plurality of trench structures 30 inside each of the IGBT regions 6 and is connected to the plurality of base regions 25 in the surface layer portion of the first main surface 3. The outer well region 56 is electrically connected to the base region 25 and the emitter region 35 inside each of the IGBT regions 6.

The outer well region 56 faces the outer cathode region 55 in the thickness direction of the chip 2. Specifically, the outer well region 56 has a width larger than the width of the outer cathode region 55 and has a portion (internal portion) that faces the outer cathode region 55 in the thickness direction of the chip 2 and a portion (peripheral edge portion) that faces the collector region 13 in the thickness direction of the chip 2. More specifically, the outer well region 56 has an inner edge portion on the internal portion side of the first main surface 3 and an outer edge portion on the peripheral edge portion side of the first main surface 3. The inner edge portion and the outer edge portion of the outer well region 56 face the collector region 13 in the thickness direction of the chip 2.

In this embodiment, the outer well region 56 faces the collector region 13 and the outer cathode region 55 at portions (internal portion and outer edge portion) that are positioned inside the outer peripheral region 10 and faces the collector region 13 at a portion (inner edge portion) that is positioned inside each of the IGBT regions 6. That is, the outer well region 56 has a portion that faces the collector region 13 in each of the IGBT regions 6 and in the outer peripheral region 10. The boundary well region 50 preferably faces an entire area of the boundary cathode region 45.

The outer well region 56 is connected to the boundary well region 50 at a portion at which the boundary region 7 and the outer peripheral region 10 are connected. The outer cathode region 55 faces the first outer wiring 43 and the second outer wiring 44 of the gate wiring 40 in the thickness direction of the chip 2.

The semiconductor device 1A includes at least one (in this embodiment, a plurality of) p-type field region 57 which is formed in the surface layer portion of the first main surface 3 in the outer peripheral region 10. The number of the field regions 57 is arbitrary and may be not less than one and not more than 20 (typically, not less than three and not more than 10).

The plurality of field regions 57 may have a p-type impurity concentration higher than that of the plurality of base regions 25. The plurality of field region 57 may have a p-type impurity concentration higher than that of the outer well region 56. As a matter of course, the plurality of field regions 57 may have a p-type impurity concentration substantially equal to that of the outer well region 56. The plurality of field regions 57 are formed in an electrically floating state.

The plurality of field regions 57 are formed in a region between the peripheral edge of the first main surface 3 and the outer well region 56 at an interval from the peripheral edge of the first main surface 3 and the outer well region 56. That is, the plurality of field regions 57 are formed in positions which do not face the outer cathode region 55 in the thickness direction of the chip 2. The plurality of field regions 57 are formed in a band shape along the outer well region 56 in a plan view. In this embodiment, the plurality of field regions 57 are formed in an annular shape (quadrangular annular shape) that surrounds the outer well region 56 in a plan view.

The plurality of field regions 57 are preferably formed deeper than the plurality of base regions 25. The plurality of field regions 57 are preferably formed at a fixed depth. The plurality of field regions 57 are preferably arranged such that an interval between the plurality of field regions 57 is gradually increased toward the peripheral edge side of the first main surface 3. The plurality of field regions 57 preferably each have a width smaller than the width of the outer well region 56. Of the plurality of field regions 57, the outermost field region 57 is preferably formed wider than the other field regions 57.

The width of each of the field regions 57 may be not less than 1 μm and not more than 50 μm. The width of each of the field regions 57 may be set at a value which falls under any one of the following ranges; not less than 1 μm and not more than 2.5 μm, not less than 2.5 μm and not more than 5 μm, not less than 5 μm and not more than 7.5 μm, not less than 7.5 μm and not more than 10 μm, not less than 10 μm and not more than 20 μm, not less than 20 μm and not more than 30 μm, not less than 30 μm and not more than 40 μm, and not less than 40 μm and not more than 50 μm. The width of each of the field regions 57 is preferably not less than 10 μm and not more than 30 μm.

The semiconductor device 1A includes an n-type channel stop region 58 which is formed in the surface layer portion of the first main surface 3 at an interval from the plurality of field regions 57 to the peripheral edge side of the first main surface 3 in the outer peripheral region 10. The channel stop region 58 has an n-type impurity concentration higher than that of the drift region 11. The channel stop region 58 may be exposed from the first to fourth side surfaces 5A to 5D.

The channel stop region 58 is formed in a band shape extending along the peripheral edge of the first main surface 3 in a plan view. In this embodiment, the channel stop region 58 is formed in an annular shape (quadrangular annular shape) that surrounds the plurality of field regions 57 in a plan view. The channel stop region 58 is formed in an electrically floating state.

The semiconductor device 1A includes an interlayer insulation film 60 that covers the main surface insulation film 39. The interlayer insulation film 60 may include at least one among a silicon oxide film, a silicon nitride film, a silicon oxynitride film and an aluminum oxide film. The interlayer insulation film 60 may include at least one among an NSG (Non-doped Silicate Glass) film as an example of the silicon oxide film, a PSG (Phosphor Silicate Glass) film and a BPSG (Boron Phosphor Silicate Glass) film. The interlayer insulation film 60 may have a single-layer structure that is made of a single insulation film or a laminated structure that includes a plurality of insulation films. The interlayer insulation film 60 has a thickness exceeding the thickness of the main surface insulation film 39.

The interlayer insulation film 60 may extend in a layer shape along the first main surface 3 and continue to the peripheral edge (first to fourth side surfaces 5A to 5D) of the chip 2. The interlayer insulation film 60 selectively covers the plurality of IGBT regions 6, the boundary region 7 and the outer peripheral region 10. The interlayer insulation film 60 covers the main surface insulation film 39, the plurality of trench separation structures 20 and the plurality of trench structures 30 in each of the IGBT regions 6. The interlayer insulation film 60 covers the main surface insulation film 39 and the gate wiring 40 in the boundary region 7 and the outer peripheral region 10.

The interlayer insulation film 60 has a plurality of contact openings 61 that expose the plurality of emitter regions 35 in each of the IGBT regions 6. In this embodiment, the plurality of contact openings 61 are formed in a one-to-one corresponding relationship with respect to the plurality of contact holes 37 and each communicate with a corresponding contact hole 37. The plurality of contact openings 61 are each formed in a band shape extending along the corresponding contact hole 37 in a plan view.

The interlayer insulation film 60 includes at least one (in this embodiment, a plurality of) gate opening 62 which selectively exposes the gate wiring 40 in the boundary region 7 and the outer peripheral region 10. The plurality of gate openings 62 may include at least one gate opening 62 that selectively exposes the pad wiring 41, at least one gate opening 62 that selectively exposes the first outer wiring 43 and at least one gate opening 62 that selectively exposes the second outer wiring 44.

The interlayer insulation film 60 includes at least one (in this embodiment, a plurality of) first well opening 63 which selectively exposes an inner edge portion of the outer well region 56 in the outer peripheral region 10. Specifically, the plurality of first well openings 63 expose the inner edge portion of the outer well region 56 in a region between the plurality of trench separation structures 20 and the gate wiring 40.

The interlayer insulation film 60 includes at least one (in this embodiment, one) second well opening 64 which selectively exposes the outer edge portion of the outer well region 56 in the outer peripheral region 10. Specifically, the second well opening 64 exposes the outer edge portion of the outer well region 56 in a region which is further on the peripheral edge side of the first main surface 3 than the gate wiring 40. The second well opening 64 is formed in a band shape extending along the plurality of IGBT regions 6. In this embodiment, the second well opening 64 is formed in an annular shape (quadrangular annular shape) that surrounds the plurality of IGBT regions 6.

The interlayer insulation film 60 includes at least one (in this embodiment, a plurality of) field opening 65 which exposes selectively at least one (in this embodiment, a plurality of) field region 57 in the outer peripheral region 10. The plurality of field openings 65 expose the plurality of field regions 57 in a one-to-one corresponding relationship. The plurality of field openings 65 are formed in band shapes extending along the plurality of field regions 57. In this embodiment, the plurality of field openings 65 are formed in annular shapes (quadrangular annular shapes) extending along the plurality of field regions 57.

The interlayer insulation film 60 includes a channel stop opening 66 which exposes the channel stop region 58 in the outer peripheral region 10. The channel stop opening 66 is formed in a band shape extending along the channel stop region 58. In this embodiment, the channel stop opening 66 is formed in an annular shape (quadrangular annular shape) extending along the channel stop region 58 and communicates with the peripheral edge of the first main surface 3.

The semiconductor device 1A includes a plurality of via electrodes 70 which are buried in the interlayer insulation film 60 so as to be electrically connected to the plurality of emitter regions 35. Specifically, the plurality of via electrodes 70 are buried in the plurality of contact openings 61 of the interlayer insulation film 60. The plurality of via electrodes 70 include a portion in contact with the chip 2 and a portion in contact with the interlayer insulation film 60. The plurality of via electrodes 70 are electrically connected to the emitter region 35 and the contact region 38 at the portion in contact with the chip 2.

Each of the via electrodes 70 may include at least one among a Ti-based metal film, a W-based metal film, an Al-based metal film and a Cu-based metal film. A Ti-based metal may include at least one of a pure Ti film (Ti film with a purity of not less than 99%) and a Ti alloy film (the same shall apply hereinafter). The Ti alloy film may be a TiN film. A W-based metal may include at least one of a pure W film (W film with a purity of not less than 99%) and a W alloy film (the same shall apply hereinafter).

An Al-based metal may include at least one of a pure Al film (Al film with a purity of not less than 99%) and an Al alloy film (the same shall apply hereinafter). The Al alloy film may include at least one among an AlCu alloy, an AlSi alloy and an AlSiCu alloy. A Cu-based metal may include at least one of a pure Cu film (Cu film with a purity of not less than 99%) and a Cu alloy film (the same shall apply hereinafter). Each of the via electrodes 70 may have a laminated structure which includes a Ti-based metal film and a W-based metal film.

The semiconductor device 1A includes the gate electrode 71 which is arranged on the interlayer insulation film 60 so as to be electrically connected to the gate wiring 40. The gate electrode 71 is made of a conductive material different from the gate wiring 40. In this embodiment, the gate electrode 71 is made of a metal film and lower in resistance value than the gate wiring 40. The gate electrode 71 may be referred to as a “gate metal.” The gate electrode 71 may include at least one among a Ti-based metal film, a W-based metal film, an Al-based metal film and a Cu-based metal film. The gate electrode 71 may have a laminated structure including a Ti-based metal film and an Al-based metal film.

The gate electrode 71 is arranged directly above the gate wiring 40 and can be routed around in an arbitrary layout in arbitrary regions of the plurality of IGBT regions 6, the boundary region 7 and the outer peripheral region 10 according to the layout of the gate wiring 40. In this embodiment, the gate electrode 71 is arranged in the boundary region 7 and the outer peripheral region 10. Specifically, the gate electrode 71 includes a gate pad electrode 72, a first gate finger electrode 73 and a second gate finger electrode 74.

The gate pad electrode 72 is arranged directly above the pad wiring 41 of the gate wiring 40. The gate pad electrode 72 enters into the gate opening 62 from above the interlayer insulation film 60 and is electrically connected to the pad wiring 41. Where a via electrode similar to the via electrode 70 is buried in the gate opening 62, the gate pad electrode 72 may be electrically connected to the pad wiring 41 via the via electrode. In this embodiment, the gate pad electrode 72 is formed in a quadrangular shape in a plan view.

In this embodiment, the gate pad electrode 72 faces the boundary cathode region 45 and the boundary well region 50 in the thickness direction of the chip 2. The gate pad electrode 72 is preferably formed at an interval from the plurality of trench structures 30 in a plan view. The gate pad electrode 72 is preferably formed at an interval from the plurality of trench separation structures 20 in a plan view.

The gate pad electrode 72 preferably has a plane area smaller than the plane area of the boundary well region 50. It is particularly preferable that the gate pad electrode 72 has a plane area smaller than the plane area of the pad wiring 41. The gate pad electrode 72 may have a plane area which is not less than the plane area of the boundary cathode region 45 or may have a plane area which is less than the plane area of the boundary cathode region 45. As a matter of course, the gate pad electrode 72 may have an area which is not less than the plane area of the pad wiring 41.

The first gate finger electrode 73 is led out directly above the first outer wiring 43 from the gate pad electrode 72. The first gate finger electrode 73 is formed in a band shape extending along the first outer wiring 43. In this embodiment, the first gate finger electrode 73 extends in a band shape along the first side surface 5A and the third side surface 5C.

The first gate finger electrode 73 enters into the gate opening 62 from above the interlayer insulation film 60 and is electrically connected to the first outer wiring 43. Where a via electrode similar to the via electrode 70 is buried inside the gate opening 62, the first gate finger electrode 73 may be electrically connected to the first outer wiring 43 via the via electrode.

In this embodiment, the first gate finger electrode 73 faces the outer cathode region 55 and the outer well region 56 in the thickness direction of the chip 2. The first gate finger electrode 73 is preferably formed at an interval from the plurality of trench structures 30 in a plan view. The first gate finger electrode 73 is preferably formed at an interval from the plurality of trench separation structures 20 (the plurality of trench structures 30) in a plan view.

The first gate finger electrode 73 is preferably formed narrower than the outer well region 56 in a cross-sectional view. It is particularly preferable that the first gate finger electrode 73 has a plane area smaller than the plane area of the first outer wiring 43. The first gate finger electrode 73 may be formed narrower than the outer cathode region 55 or may be formed wider than the outer cathode region 55 in a cross-sectional view.

The second gate finger electrode 74 is led out directly above the second outer wiring 44 from the gate pad electrode 72. The second gate finger electrode 74 is formed in a band shape extending along the second outer wiring 44. In this embodiment, the second gate finger electrode 74 extends in a band shape along the second side surface 5B and the third side surface 5C.

The second gate finger electrode 74 enters into the gate opening 62 from above the interlayer insulation film 60 and is electrically connected to the second outer wiring 44. Where a via electrode similar to the via electrode 70 is buried in the gate opening 62, the second gate finger electrode 74 may be electrically connected to the second outer wiring 44 via the via electrode.

In this embodiment, the second gate finger electrode 74 faces the outer cathode region 55 and the outer well region 56 in the thickness direction of the chip 2. The second gate finger electrode 74 is preferably formed at an interval from the plurality of trench structures 30 in a plan view. The first gate finger electrode 73 is preferably formed at an interval from the plurality of trench separation structures 20 (the plurality of trench structures 30) in a plan view.

The second gate finger electrode 74 is preferably formed narrower than the outer well region 56 in a cross-sectional view. It is particularly preferable that the second gate finger electrode 74 has a plane area smaller than the plane area of the first outer wiring 43. The second gate finger electrode 74 may be formed narrower than the outer cathode region 55 or may be formed wider than the outer cathode region 55 in a cross-sectional view.

The semiconductor device 1A includes the emitter electrode 75 which is arranged on the interlayer insulation film 60 at an interval from the gate wiring 40. The emitter electrode 75 is made of a conductive material different from the gate wiring 40. In this embodiment, the emitter electrode 75 is made of a metal film. The emitter electrode 75 may be referred to as an “emitter metal.” The emitter electrode 75 may include at least one among a Ti-based metal film, a W-based metal film, an Al-based metal film and a Cu-based metal film. The emitter electrode 75 may have a laminated structure including a Ti-based metal film and an Al-based metal film.

The emitter electrode 75 is arranged on the interlayer insulation film 60 so as to cover the plurality of IGBT regions 6. The emitter electrode 75 collectively covers the plurality of via electrodes 70 and are electrically connected to the plurality of emitter regions 35 via the plurality of via electrodes 70. In this embodiment, the emitter electrode 75 has a portion which covers the boundary wiring 42 of the gate wiring 40 across the interlayer insulation film 60. That is, the emitter electrode 75 has a portion which faces the gate wiring 40 (boundary wiring 42), the boundary cathode region 45 and the boundary well region 50 in the thickness direction of the chip 2.

The emitter electrode 75 is led out to the outer peripheral region 10 from the plurality of IGBT regions 6 in a plan view. In this embodiment, the emitter electrode 75 has a portion which covers the first outer wiring 43 and the second outer wiring 44 of the gate wiring 40 across the interlayer insulation film 60 in the outer peripheral region 10. That is, the emitter electrode 75 has a portion which faces the gate wiring 40 (first outer wiring 43 and second outer wiring 44), the outer cathode region 55 and the outer well region 56 in the thickness direction of the chip 2.

The emitter electrode 75 enters into the first well opening 63 and the second well opening 64 and is electrically connected to the outer well region 56. Specifically, in this embodiment, the emitter electrode 75 includes an emitter pad electrode 76 and an emitter finger electrode 77.

The emitter pad electrode 76 is arranged on the interlayer insulation film 60 so as to cover the plurality of IGBT regions 6 and the boundary region 7. The emitter pad electrode 76 faces the gate wiring 40 across the interlayer insulation film 60 and is electrically connected to the plurality of emitter regions 35 via the plurality of via electrodes 70. The emitter pad electrode 76 is led out to the outer peripheral region 10 from the plurality of IGBT regions 6 and enters into the first well opening 63 from above the interlayer insulation film 60. The emitter pad electrode 76 is electrically connected to an inner edge portion of the outer well region 56 inside the first well opening 63.

The emitter finger electrode 77 is led out directly above the outer peripheral region 10 from the emitter pad electrode 76. The emitter finger electrode 77 is led out in a region between the peripheral edge of the first main surface 3 and the gate electrode 71 and extends in a band shape along the gate electrode 71. In this embodiment, the emitter finger electrode 77 is formed in an annular shape (quadrangular annular shape) that surrounds the gate electrode 71 and the emitter pad electrode 76. The emitter finger electrode 77 enters into the second well opening 64 from above the interlayer insulation film 60. The emitter finger electrode 77 is electrically connected to an outer edge portion inside the second well opening 64.

Where a via electrode similar to the via electrode 70 is buried in the first well opening 63 and/or the second well opening 64, the emitter electrode 75 may be electrically connected to the outer well region 56 via the via electrode.

The semiconductor device 1A includes a plurality of field electrodes 78 which are formed on the interlayer insulation film 60 in the outer peripheral region 10. The plurality of field electrodes 78 may include at least one among a Ti-based metal film, a W-based metal film, an Al-based metal film and a Cu-based metal film. The plurality of field electrodes 78 may have a laminated structure including a Ti-based metal film and an Al-based metal film.

The plurality of field electrodes 78 are formed in a one-to-one corresponding relationship to the plurality of field regions 57. The plurality of field electrodes 78 are each formed in a band shape along a corresponding field region 57. In this embodiment, the plurality of field electrodes 78 are each formed in an annular shape (quadrangular annular shape) extending along the corresponding field region 57.

The plurality of field electrodes 78 enter into corresponding field openings 65 from above the interlayer insulation film 60 and are electrically connected to corresponding field regions 57. The field electrode 78 is formed in an electrically floating state. The peripheral field electrode 78 at the outermost periphery includes a lead-out portion which is led out toward the peripheral edge side of the first main surface 3 and may be formed wider than the other field electrodes 78.

The semiconductor device 1A includes a channel stop electrode 79 which is formed on the interlayer insulation film 60 in the outer peripheral region 10. The channel stop electrode 79 may include at least one among a Ti-based metal film, a W-based metal film, an Al-based metal film and a Cu-based metal film. The channel stop electrode 79 may have a laminated structure which includes a Ti-based metal film and an Al-based metal film. The channel stop electrode 79 is formed in a band shape extending along the channel stop region 58. In this embodiment, the channel stop electrode 79 is formed in an annular shape (quadrangular annular shape) extending along the channel stop region 58.

The channel stop electrode 79 enters into the channel stop opening 66 from above the interlayer insulation film 60 and is electrically connected to the channel stop region 58. The channel stop electrode 79 may be formed at an interval inward (to the IGBT region 6 side) from the peripheral edge of the first main surface 3 so as to expose the channel stop region 58. The channel stop electrode 79 is formed in an electrically floating state.

The semiconductor device 1A includes a collector electrode 80 which covers the second main surface 4. The collector electrode 80 is electrically connected to the collector region 13, the boundary cathode region 45 and the outer cathode region 55 which are exposed from the second main surface 4. The collector electrode 80 forms an ohmic contact with the collector region 13, the boundary cathode region 45 and the outer cathode region 55. The collector electrode 80 may cover an entire area of the second main surface 4 so as to continue to the peripheral edge (first to fourth side surfaces 5A to 5D) of the chip 2.

The collector electrode 80 may include at least one among a Ti film, an Ni film, a Pd film, an Au film, an Ag film and an Al film. The collector electrode 80 may have a single film structure that includes a Ti film, an Ni film, an Au film, an Ag film or an Al film. The collector electrode 80 may have a laminated structure in which at least two among a Ti film, an Ni film, a Pd film, an Au film, an Ag film and an Al film are laminated in an arbitrary mode. The collector electrode 80 preferably includes at least a Ti film which directly covers the second main surface 4. The collector electrode 80 may have a laminated structure which, for example, includes a Ti film, an Ni film, a Pd film and an Au film that are laminated in this order from the second main surface 4 side.

As described so far, the semiconductor device 1A includes IGBT structures TR1, TR2 formed in each of the IGBT regions 6, the boundary diode D1 formed in the boundary region 7 and the outer diode D2 formed in the outer peripheral region 10. Each of the IGBT structures TR1, TR2 includes the trench structure 30 as a gate, the emitter region 35 as an emitter and the collector region 13 as a collector.

The boundary diode D1 includes the boundary well region 50 as an anode and the boundary cathode region 45 as a cathode. The anode of the boundary diode D1 is electrically connected to an emitter of each of the IGBT structures TR1, TR2, and the cathode of the boundary diode D1 is electrically connected to a collector of each of the IGBT regions 6. Thereby, the boundary diode D1 functions as a first reflux diode relating to each of the IGBT structures TR1, TR2.

The outer diode D2 includes the outer well region 56 as an anode and the outer cathode region 55 as a cathode. The anode of the outer diode D2 is electrically connected to an emitter of each of the IGBT structures TR1, TR2, and the cathode of the outer diode D2 is electrically connected to a collector of each of the IGBT regions 6. Thereby, the outer diode D2 is connected in parallel to the boundary diode D1 in a forward direction. Also, the outer diode D2 functions as a second reflux diode relating to each of the IGBT structures TR1, TR2.

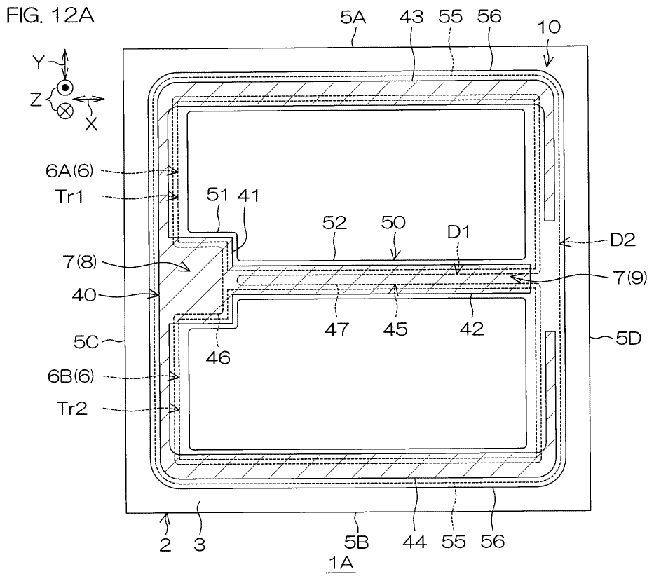

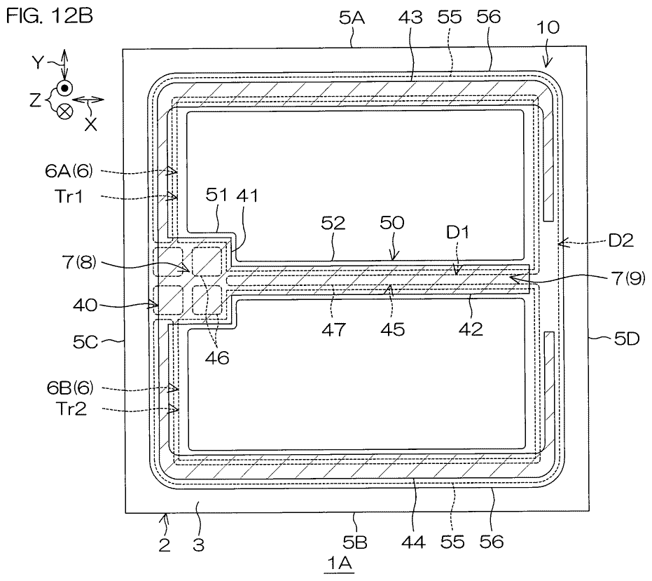

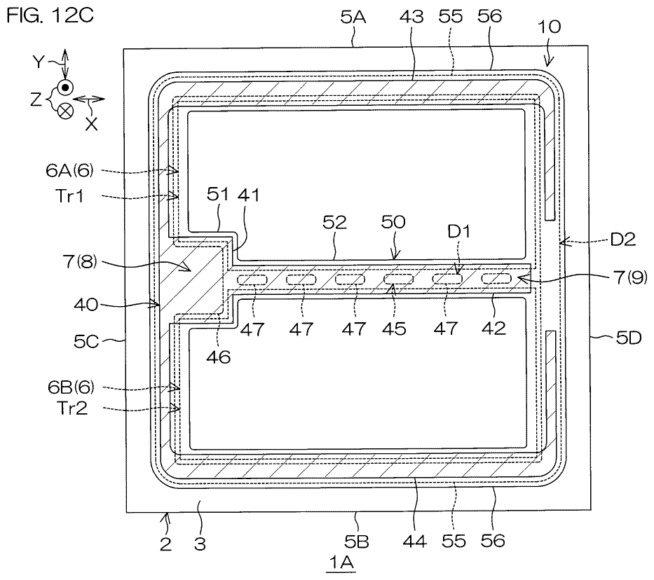

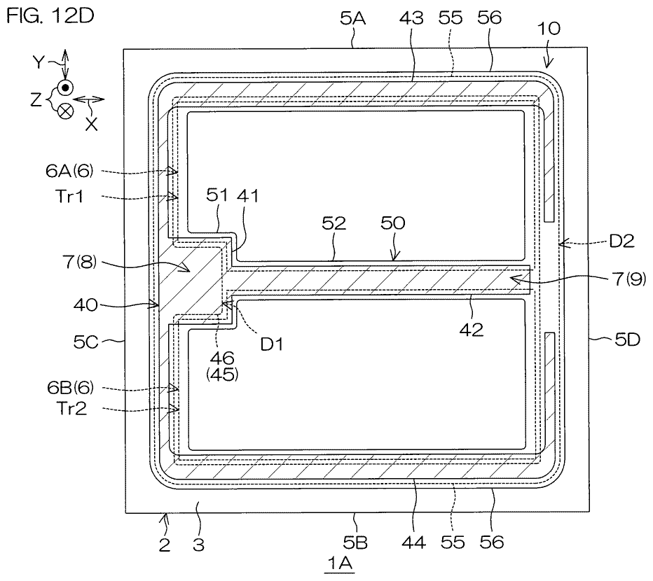

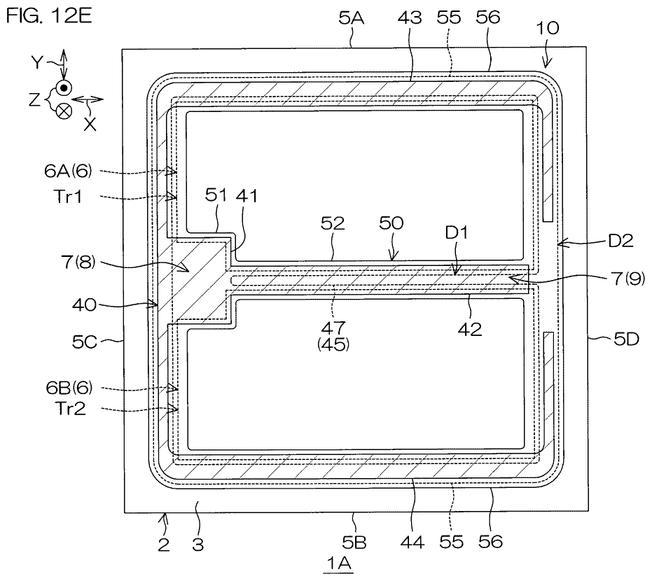

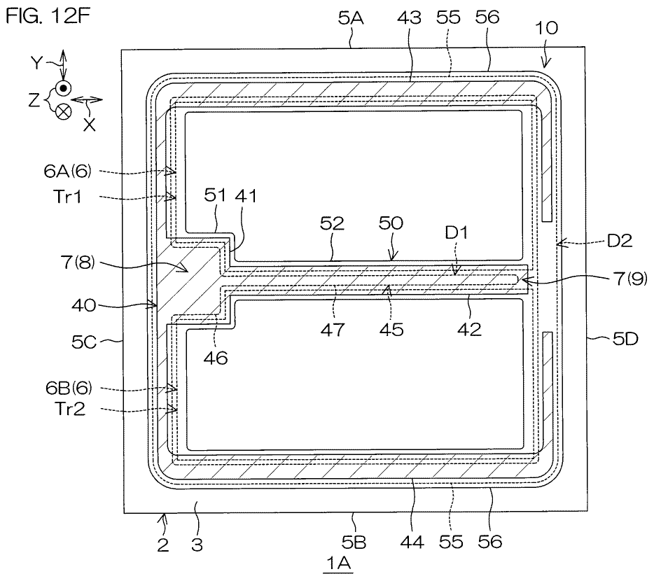

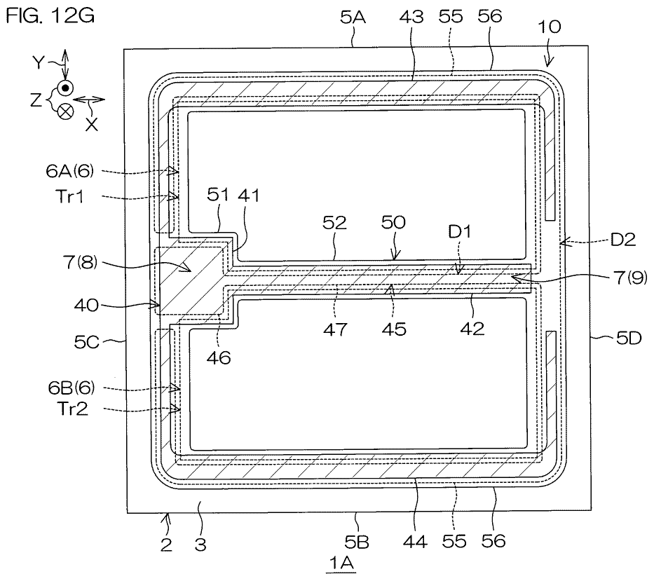

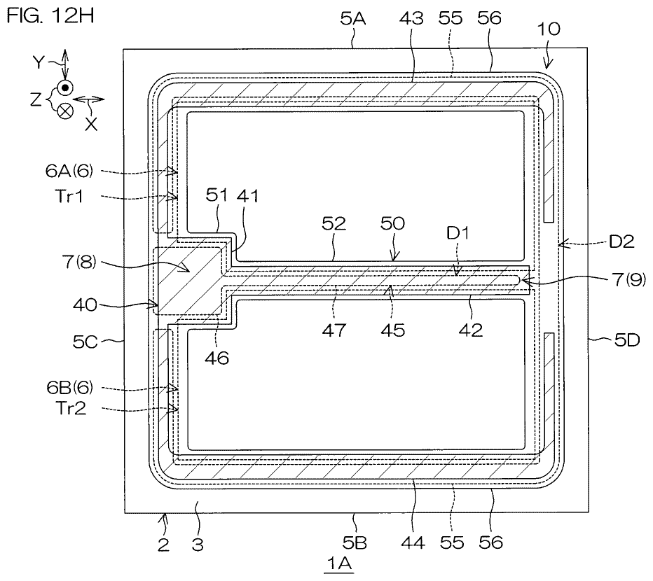

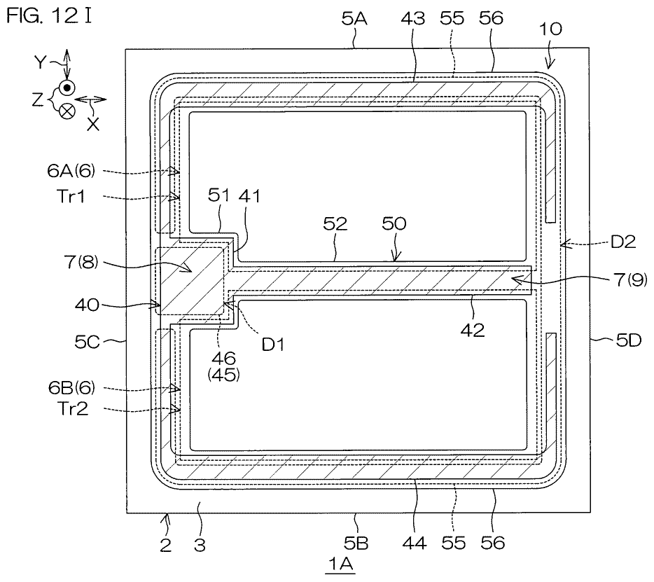

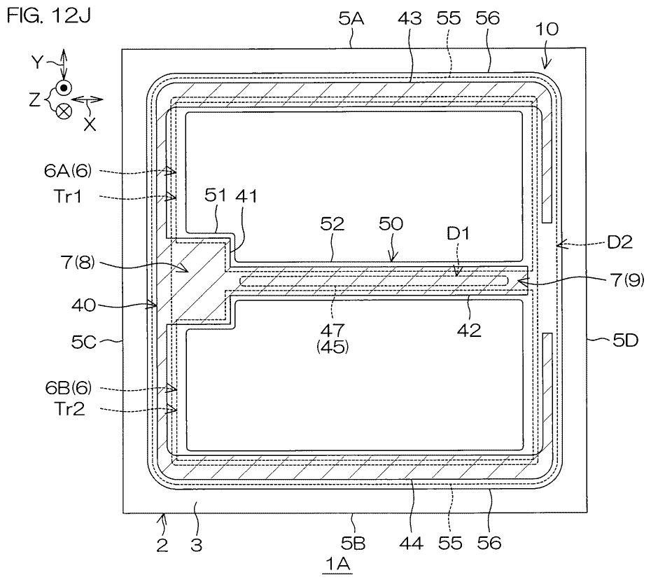

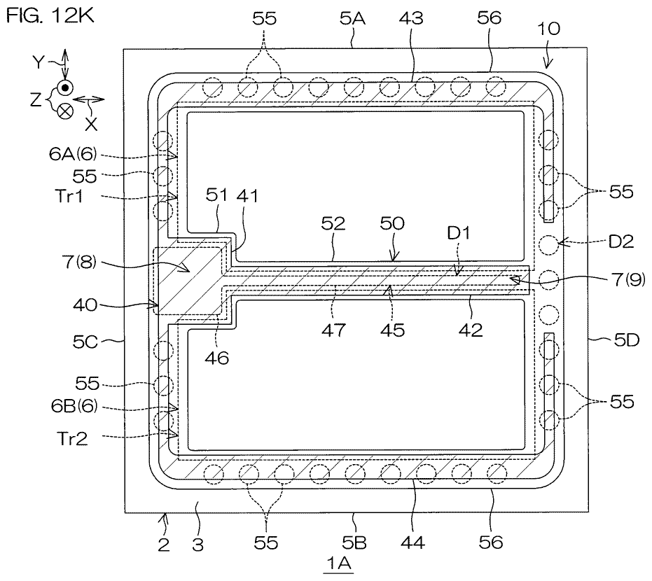

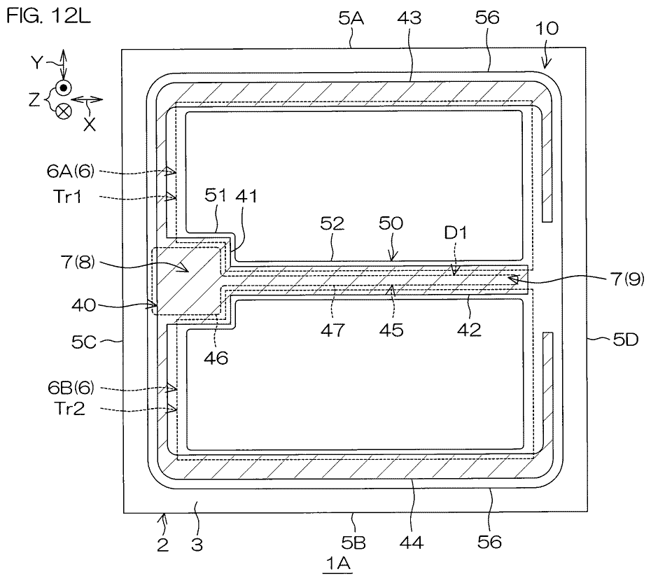

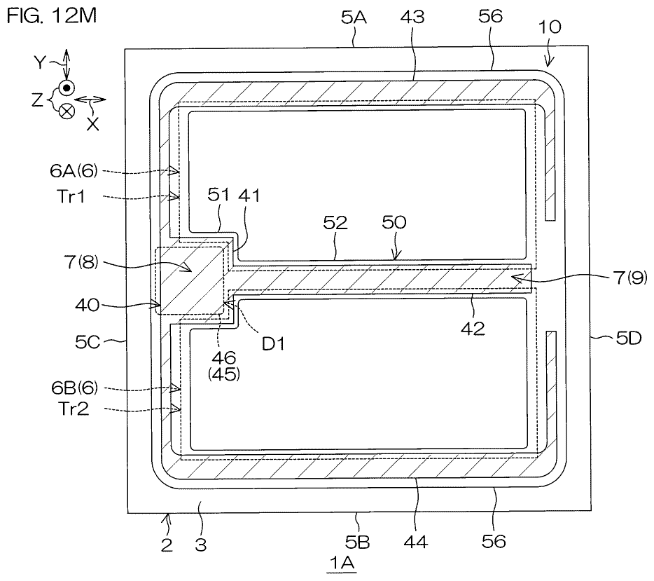

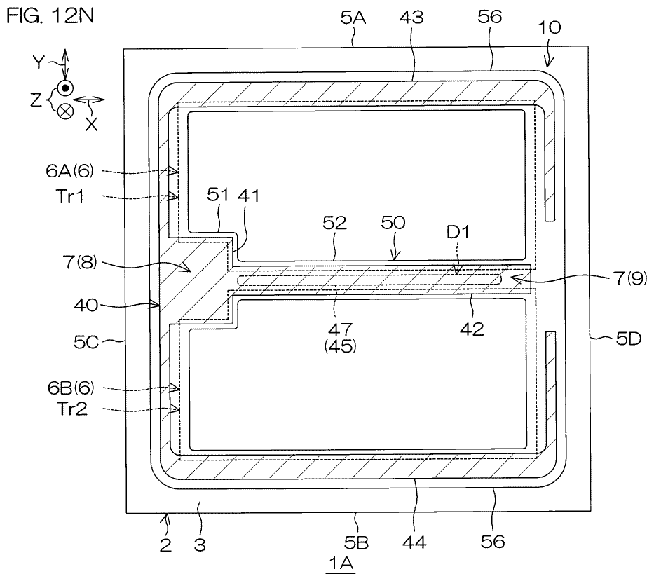

In FIG. 1 to FIG. 11, there is shown one layout example of the boundary cathode region 45 and the outer cathode region 55 (hereinafter, referred to as a “first layout example”). However, the layout example of the boundary cathode region 45 and the outer cathode region 55 is not limited to the first layout example. Hereinafter, other layout examples of the boundary cathode region 45 and the outer cathode region 55 are shown. FIG. 12A to FIG. 12N are plan views which show respectively second to fifteenth layout examples of the boundary cathode region 45 and the outer cathode region 55.

With reference to FIG. 12A, in the second layout example, the boundary cathode region 45 includes the second cathode region 47 formed at an interval from the first cathode region 46. A length of the second cathode region 47 in the first direction X is arbitrary and adjusted whenever necessary.

With reference to FIG. 12B, in the third layout example, the boundary cathode region 45 includes the plurality of first cathode regions 46 which are arrayed at an interval in the first region 8 of the boundary region 7. The plurality of first cathode regions 46 may be arrayed at an interval in the first direction X and/or in the second direction Y. Each of the first cathode regions 46 may be formed in a circular shape, an elliptical shape, a quadrangular shape, a rectangular shape or a polygonal shape in a plan view.

With reference to FIG. 12C, in the fourth layout example, the boundary cathode region 45 includes the plurality of second cathode regions 47 which are arrayed at an interval in the second region 9 of the boundary region 7. The plurality of second cathode regions 47 may be arrayed at an interval in the first direction X and/or in the second direction Y. Each of the second cathode regions 47 may be formed in a circular shape, an elliptical shape, a quadrangular shape, a rectangular shape or a polygonal shape in a plan view.

With reference to FIG. 12D, in the fifth layout example, the boundary cathode region 45 includes only the first cathode region 46 and does not include the second cathode region 47. With reference to FIG. 12E, in the sixth layout example, the boundary cathode region 45 does not include the first cathode region 46 but includes only the second cathode region 47.

With reference to FIG. 12F, in the seventh layout example, the outer cathode region 55 is connected to the first cathode region 46 of the boundary cathode region 45 and formed at an interval from the second cathode region 47 of the boundary cathode region 45. With reference to FIG. 12G, in the eighth layout example, the outer cathode region 55 is connected to the second cathode region 47 of the boundary cathode region 45 and formed at an interval from the first cathode region 46 of the boundary cathode region 45. With reference to FIG. 12H, in the nineth layout example, the outer cathode region 55 is formed at an interval from the first cathode region 46 and the second cathode region 47 of the boundary cathode region 45.

With reference to FIG. 12I, in the tenth layout example, the boundary cathode region 45 includes only the first cathode region 46 and does not include the second cathode region 47. In this structure, the outer cathode region 55 is formed at an interval from the first cathode region 46. With reference to FIG. 12J, in the eleventh layout example, the boundary cathode region 45 does not include the first cathode region 46 but include only the second cathode region 47. In this structure, the outer cathode region 55 is formed at an interval from the second cathode region 47.

With reference to FIG. 12K, in the twelfth layout example, the plurality of outer cathode regions 55 are arrayed at an interval along the peripheral edge (the plurality of IGBT regions 6) of the first main surface 3. The plurality of outer cathode regions 55 may be arrayed at an interval in the first direction X and/or in the second direction Y. Each of the outer cathode regions 55 may be formed in a circular shape, an elliptical shape, a quadrangular shape, a rectangular shape or a polygonal shape in a plan view.

With reference to FIG. 12L, in the thirteenth layout example, the boundary cathode region 45 includes the first cathode region 46 and the second cathode region 47. On the other hand, no outer cathode region 55 is formed. That is, only the collector region 13 and the boundary cathode region 45 are exposed from the second main surface 4.

With reference to FIG. 12M, in the fourteenth layout example, the boundary cathode region 45 includes only the first cathode region 46 and does not include the second cathode region 47. On the other hand, no outer cathode region 55 is formed. That is, only the collector region 13 and the first cathode region 46 are exposed from the second main surface 4.

With reference to FIG. 12N, in the fifteenth layout example, the boundary cathode region 45 does not include the first cathode region 46 but includes only the second cathode region 47. On the other hand, no outer cathode region 55 is formed. That is, only the collector region 13 and the second cathode region 47 are exposed from the second main surface 4.

The first to fifteenth layout examples (with reference to FIG. 1 to FIG. 12N) can be appropriately combined among them. Therefore, the semiconductor device 1A may have a layout in which features (one of or both of the feature of the boundary cathode region 45 and the feature of the outer cathode region 55) shown in at least two layout examples among the first to fifteenth layout examples are combined in an arbitrary mode.

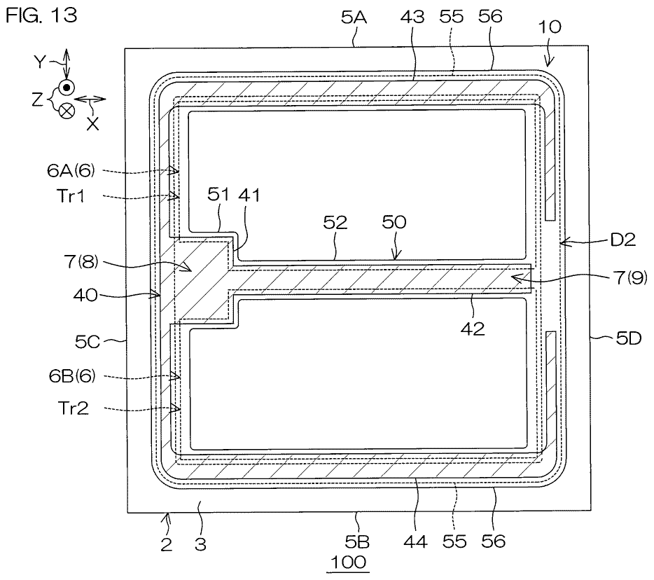

FIG. 13 is a plan view which shows a semiconductor device 100 according to a reference example. With reference to FIG. 13, the semiconductor device 100 includes the plurality of IGBT structures Tr1, Tr2 and an outer diode D2 but does not include the boundary diode D1 (boundary cathode region 45). Other structures of the semiconductor device 100 are the same as those of the semiconductor device 1A.

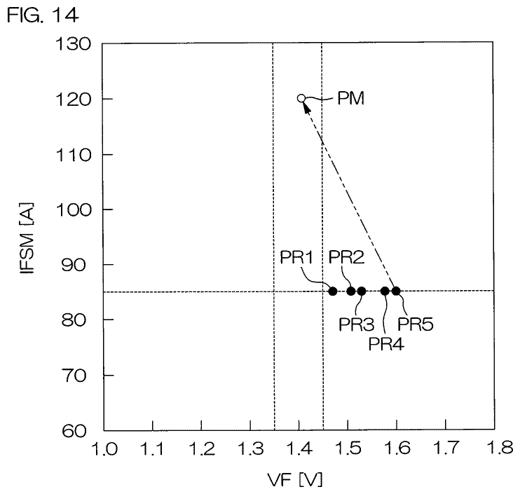

FIG. 14 is a graph which shows a relationship between a peak surge current IFSM and a forward voltage VF. In FIG. 14, the ordinate axis indicates the peak surge current IFSM [A], and the abscissa axis indicates the forward voltage VF [V] during a normal operation. The peak surge current IFSM is a peak value of a commercial sinusoidal half-wave current) (50 Hz or 60 Hz) of one cycle or more which is allowed as long as no breakage occurs. In FIG. 14, first to fifth reference plot points PR1 to PR5 and a main plot point PM are shown.

The first to fifth reference plot points PR1 to PR5 indicate characteristics of the semiconductor device 100 according to the reference example. The first to fifth reference plot points PR1 to PR5 are characteristics obtained by increasing and decreasing a plane area (width of outer cathode region 55) of the outer cathode region 55 in the outer peripheral region 10. The plane area of the outer cathode region 55 is decreased in a descending order of the first reference plot point PR1 (plane area=maximum), the second reference plot point PR2, the third reference plot point PR3, the fourth reference plot point PR4, and the fifth reference plot point PR5 (plane area=minimum).

On the other hand, the main plot point PM indicates characteristics of the semiconductor device 1A. In the semiconductor device 1A, a total plane area of the boundary diode D1 and the outer diode D2 is set at a value substantially equal to a plane area of the outer diode D2 according to the fifth reference plot point PR5.

With reference to the first to fifth reference plot points PR1 to PR5, in the semiconductor device 100 according to the reference example, even where the outer diode D2 is increased or decreased in plane area, the peak surge current IFSM is about 85 A, and no change in peak surge current IFSM is found. On the other hand, in the semiconductor device 100 according to the reference example, in association with an increase or a decrease in plane area of the outer diode D2, the forward voltage VF is increased or decreased during a normal operation. Specifically, the forward voltage VF of the semiconductor device 100 according to the reference example is decreased with an increase in plane area of the outer diode D2 and increased with a decrease in plane area of the outer diode D2.

The forward voltage VF at the first reference plot point PR1 is about 1.48 V and the forward voltage VF at the fifth reference plot point PR5 is about 1.6 V. That is, the forward voltage VF of the semiconductor device 100 according to the reference example is in excess of 1.45 V and not more than 1.6 V and does not fall down to a value of not more than 1.45 V. From this fact, it has been found that in a configuration of the semiconductor device 100 according to the reference example, a tolerance for the peak surge current IFSM is relatively low and a conduction loss due to the forward voltage VF during a normal operation is relatively high.

On the other hand, with reference to the main plot point PM, in the semiconductor device 1A, as compared with the semiconductor device 100 according to the reference example, the peak surge current IFSM is increased and the forward voltage VF during a normal operation is decreased. Specifically, in the semiconductor device 1A, the peak surge current IFSM which is not less than 90 A and not more than 125 A (specifically, not more than 120 A) is applicable. Also, the forward voltage VF during a normal operation is not more than 1.45 V. Specifically, the forward voltage VF falls under a range of not less than 1.35 V and not more than 1.45 V.

In the semiconductor device 1A, a total plane area of the boundary diode D1 and the outer diode D2 is set at a value substantially equal to a plane area of the outer diode D2 according to the fifth reference plot point PR5. Therefore, it is considered that even where the boundary diode D1 is formed together with the outer diode D2, the peak surge current IFSM and the forward voltage VF of the semiconductor device 1A are similar to a case of the fifth reference plot point PR5.

However, the peak surge current IFSM and the forward voltage VF of the semiconductor device 1A are both superior to the peak surge current IFSM and the forward voltage VF according to the fifth reference plot point PR5. That is, in the configuration according to the semiconductor device 1A, as compared with the semiconductor device 100 according to the reference example, a tolerance for the peak surge current IFSM is increased and a conduction loss due to the forward voltage VF is decreased, which are unanticipated results. It has been found from this fact that according to the boundary diode D1, the peak surge current IFSM can be adjusted and improved without being restricted to the peak surge current IFSM due to a plane area of the outer diode D2.

As described so far, the semiconductor device 1A includes the chip 2, the plurality of IGBT regions 6, the boundary region 7, the n-type boundary cathode region 45 and the p-type boundary well region 50. The chip 2 has the first main surface 3 on one side and the second main surface 4 on the other side. The plurality of IGBT regions 6 are provided at an interval in the chip 2. The boundary region 7 is provided in a region between the plurality of IGBT regions 6 in the chip 2. The boundary cathode region 45 is formed in the surface layer portion of the second main surface 4 in the boundary region 7. The boundary well region 50 is formed in the surface layer portion of the first main surface 3 in the boundary region 7.

According to this structure, the boundary diode D1 which includes the boundary cathode region 45 and the boundary well region 50 can be formed by using the boundary region 7 between the plurality of IGBT regions 6. It is, thereby, possible to suppress an electrical influence on the boundary diode D1 from the plurality of IGBT regions 6 and suppress an electrical influence on the plurality of IGBT regions 6 from the boundary diode D1. Also, since a size of the boundary region 7 is less likely to be influenced by a size of the chip 2, it is possible to form the boundary diode D1 having stable electrical characteristics in the chip 2 that is different in size. Thus, it is possible to provide the semiconductor device 1A contributing to an improvement in electrical characteristics.

As an example, where the cathode region is formed directly below the IGBT region 6, carriers (electrons) which flow through the IGBT region 6 flow into a cathode region during a start-up operation of the IGBT region 6. As a result, a delay in switching occurs in the IGBT region 6 and a snapback waveform is formed in a current flowing through the IGBT region 6 (specifically, an emitter collector current).

In contrast, according to a structure in which the boundary cathode region 45 is formed in the boundary region 7, it is possible to prevent carriers (electrons) which flow through the plurality of IGBT regions 6 from flowing into the boundary cathode region 45. It is, thereby, possible to suppress a deterioration in switching characteristics that is caused by a snapback phenomenon. On the other hand, since the boundary diode D1 is less likely to be electrically influenced from the plurality of IGBT regions 6, operation of the boundary diode D1 is made stable. Thus, it is possible to provide the semiconductor device 1A which contributes to an improvement in electrical characteristics.

It is preferable that the boundary cathode region 45 is configured such that a collector potential can be applied and the boundary well region 50 is configured such that an emitter potential can be applied. That is, the boundary diode D1 is preferably formed as a reflux diode for the plurality of IGBT regions 6.

The boundary well region 50 preferably has a portion which faces the boundary cathode region 45 in the thickness direction of the chip 2. According to this structure, a current channel which connects the boundary cathode region 45 and the boundary well region 50 can be appropriately shortened. Thus, it is possible to form the boundary diode D1 having stable diode characteristics.

The boundary cathode region 45 is preferably formed narrower than the boundary region 7. According to this structure, a current channel which connects the boundary cathode region 45 and the boundary well region 50 can be appropriately restricted inside the boundary region 7. The boundary well region 50 is preferably formed wider than the boundary cathode region 45. The boundary well region 50 is preferably formed wider than the boundary region 7. According to these structures, while carriers (electrons) are prevented from flowing into the boundary cathode region 45, an electric field in the boundary region 7 can be relaxed by the boundary well region 50.

The semiconductor device 1A preferably includes the p-type collector region 13 which is formed in the surface layer portion of the second main surface 4 in the boundary region 7. In this case, the boundary well region 50 preferably has a portion which faces the collector region 13 in the thickness direction of the chip 2. According to this structure, it is possible to suppress a dispersion of diode current flowing between the boundary cathode region 45 and the boundary well region 50 by the collector region 13. That is, according to this structure, a current channel which connects the boundary cathode region 45 and the boundary well region 50 can be appropriately restricted inside the boundary region 7.

The semiconductor device 1A preferably includes the gate wiring 40 which is arranged above the first main surface 3 in the boundary region 7. In this case, the boundary cathode region 45 preferably faces the gate wiring 40 in the thickness direction of the chip 2. Also, the boundary well region 50 preferably faces the gate wiring 40 in the thickness direction of the chip 2.

According to these structures, the boundary region 7 can be used as a region for arranging the gate wiring 40, and also the boundary diode D1 can be formed by using the boundary region 7 positioned directly below the gate wiring 40. Thus, it is possible to prevent the chip 2 from an increase in size due to the gate wiring 40 and the boundary diode D1.

In the above-described structure, the boundary well region 50 is preferably formed wider than the gate wiring 40. Also, the boundary cathode region 45 is preferably formed narrower than the gate wiring 40.

The semiconductor device 1A preferably includes the p-type base region 25 which is formed in the surface layer portion of the first main surface 3 of each of the IGBT regions 6. In this case, the boundary well region 50 is preferably formed deeper than the base region 25. According to this structure, it is possible to relax an electric field in the boundary region 7 by the boundary well region 50 and improve a withstand voltage.

The boundary well region 50 is preferably electrically connected to the base region 25. According to this structure, it is possible to appropriately improve an electric field relaxation effect by the boundary well region 50. The boundary cathode region 45 preferably does not face the base region 25 in the thickness direction of the chip 2. According to this structure, it is possible to appropriately prevent the carriers (electrons) from flowing into the boundary cathode region 45.

The semiconductor device 1A preferably includes the plurality of trench structures 30. The plurality of trench structures 30 are formed in the first main surface 3 by penetrating through the base region 25 in each of the IGBT regions 6 and configured such that a gate potential can be applied. In this case, the boundary well region 50 is preferably formed deeper than the trench structure 30 of each of the IGBT regions 6. According to this structure, it is possible to relax an electric field in the boundary region 7 by the boundary well region 50 formed deeper than the trench structure 30 and improve a withstand voltage.

The boundary cathode region 45 preferably does not face the trench structure 30 of each of the IGBT regions 6 in the thickness direction of the chip 2. According to this structure, it is possible to appropriately prevent carriers (electrons) from flowing into the boundary cathode region 45. The boundary well region 50 may be in contact with the trench structure 30 of each of the IGBT regions 6.

The gate wiring 40 is preferably electrically connected to the trench structure 30 of each of the IGBT regions 6. Each of the trench structures 30 preferably includes the gate trench 31 that is formed in the first main surface 3, the gate insulation film 32 that covers a wall surface of the gate trench 31 and the gate buried electrode 33 that is buried in the gate trench 31 across the gate insulation film 32. In this case, it is preferable that the gate wiring 40 is electrically and mechanically connected to the gate buried electrode 33. The gate wiring 40 may be formed integrally with the gate buried electrode 33.

The boundary region 7 may include the relatively wide first region 8 and the second region 9 which is narrower than the first region 8. The gate wiring 40 may include the relatively wide pad wiring 41 (first wiring) in the first region 8 and may include the boundary wiring 42 (second wiring) which is narrower than the pad wiring 41 in the second region 9.

In this case, the boundary well region 50 preferably faces at least one of the pad wiring 41 and the boundary wiring 42 in the thickness direction of the chip 2. Also, the boundary cathode region 45 preferably faces at least one of the pad wiring 41 and the boundary wiring 42 in the thickness direction of the chip 2.

The semiconductor device 1A preferably includes the interlayer insulation film 60 which is formed on the first main surface 3. In this case, the semiconductor device 1A preferably includes the emitter electrode 75 which is arranged on the interlayer insulation film 60 so as to be electrically connected to the plurality of IGBT regions 6. The emitter electrode 75 may face the gate wiring 40 across the interlayer insulation film 60.

In a different point of view, the semiconductor device 1A includes the chip 2, the plurality of IGBT regions 6A, 6B, the boundary region 7, the outer peripheral region 10, the plurality of IGBT structures Tr1, Tr2, the boundary diode D1 and the outer diode D2. The chip 2 has the first main surface 3 on one side and the second main surface 4 on the other side. The plurality of IGBT regions 6A, 6B are set at an interval in the first main surface 3. The boundary region 7 is set between the plurality of IGBT regions 6A, 6B in the first main surface 3. The outer peripheral region 10 is set around the plurality of IGBT regions 6A, 6B in the first main surface 3.

The plurality of IGBT structures Tr1, Tr2 are formed in the plurality of IGBT regions 6A, 6B. The boundary diode D1 is formed in the boundary region 7. The outer diode D2 is formed in the outer peripheral region 10. According to this structure, as compared with the structure (refer to FIG. 13) in which only the outer diode D2 is formed, it is possible to improve a tolerance for the peak surge current IFSM and reduce a conduction loss which is caused by the forward voltage VF during a normal operation (refer to FIG. 14). It is, thus, possible to apply the semiconductor device 1A which contributes to an improvement in electrical characteristics.

The outer diode D2 is preferably connected to the boundary diode D1 in parallel in a forward direction. The boundary diode D1 is preferably formed as a first reflux diode of the IGBT structures Tr1, Tr2. The outer diode D2 is preferably formed as a second reflux diode of the IGBT structures Tr1, Tr2.

The boundary diode D1 preferably includes the boundary cathode region 45 which is formed in the surface layer portion of the second main surface 4 in the boundary region 7 and the boundary well region 50 (boundary anode region) which is formed in the surface layer portion of the first main surface 3 in the boundary region 7. The outer diode D2 preferably includes the outer cathode region 55 (outer anode region), which is formed in the surface layer portion of the second main surface 4 in the outer peripheral region 10 and the outer well region 56 which is formed in the surface layer portion of the first main surface 3 in the outer peripheral region 10.

The boundary cathode region 45 is preferably formed in the boundary region 7 at an interval from each of the IGBT regions 6A, 6B in a plan view. The boundary well region 50 preferably has a portion which faces the boundary cathode region 45 in the thickness direction of the chip 2. The boundary well region 50 is preferably formed wider than the boundary cathode region 45.

The boundary region 7 may be set in a band shape extending in one direction in a plan view. The boundary cathode region 45 may be formed in a band shape extending in one direction in a plan view. The boundary well region 50 may be formed in a band shape extending in one direction in a plan view.

The outer cathode region 55 is preferably formed in the outer peripheral region 10 at an interval from each of the IGBT regions 6A, 6B in a plan view. The outer well region 56 preferably has a portion that faces the outer cathode region 55 in the thickness direction of the chip 2. The outer well region 56 is preferably formed wider than the outer cathode region 55.

The outer cathode region 55 may surround the plurality of IGBT regions 6A, 6B in a plan view. The outer well region 56 may surround the plurality of IGBT regions 6A, 6B in a plan view. The outer cathode region 55 may be connected to the boundary cathode region 45. The outer well region 56 may be connected to the outer well region 56.

The semiconductor device 1A preferably includes the collector region 13 which is formed in the surface layer portion of the second main surface 4 in each of the IGBT regions 6A, 6B. The collector region 13 preferably has a portion that is positioned at the surface layer portion of the second main surface 4 of the boundary region 7. The collector region 13 preferably has a portion that is positioned at the surface layer portion of the second main surface 4 of the outer peripheral region 10.

Each of the IGBT structures Tr1, Tr2 preferably has a base region 25 which is formed in the surface layer portion of the first main surface 3 of each of the IGBT regions 6A, 6B. Each of the IGBT structures Tr1, Tr2 preferably has the plurality of trench structures 30 which are formed so as to penetrate through the base region 25 in the first main surface 3 of each of the IGBT regions 6A, 6B. Each of the IGBT structures Tr1, Tr2 preferably includes the emitter region 35 which is formed in a region along each trench structure 30 at the surface layer portion of the first main surface 3 of each of the IGBT regions 6A, 6B.

The semiconductor device 1A preferably includes the plurality of trench separation structures 20 which are formed in the first main surface 3 so as to define the plurality of IGBT regions 6A, 6B. In this case, the boundary diode D1 is preferably formed in a region held between the plurality of trench separation structures 20 in the boundary region 7.

The semiconductor device 1A may include the boundary wiring 42 which is arranged above the first main surface 3 of the boundary region 7. In this case, the boundary diode D1 may face the boundary wiring 42 in the thickness direction of the chip 2. The semiconductor device 1A may include the first outer wiring 43 (second outer wiring 44) which is arranged above the first main surface 3 of the outer peripheral region 10. In this case, the outer diode D2 may face the first outer wiring 43 (second outer wiring 44) in the thickness direction of the chip 2.

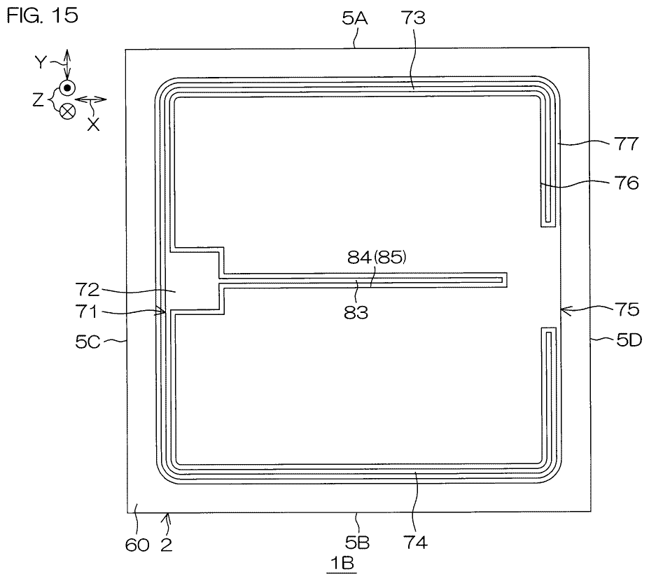

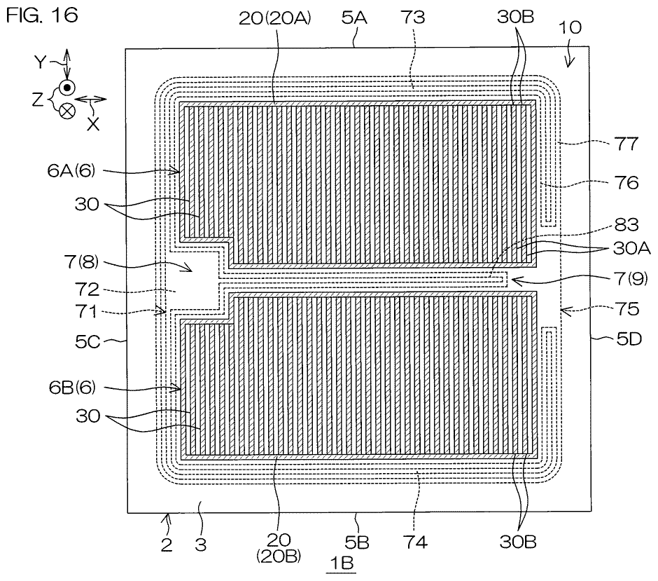

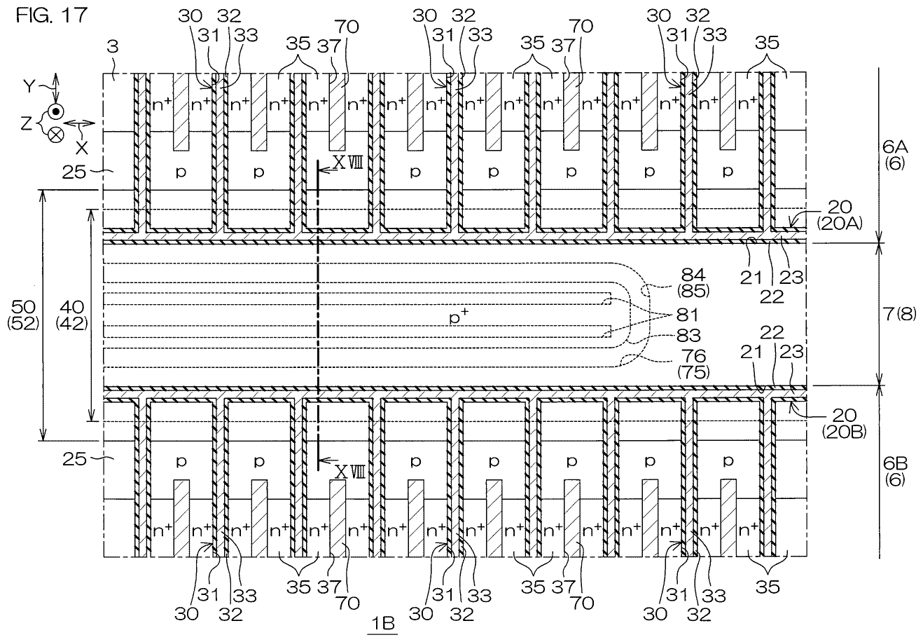

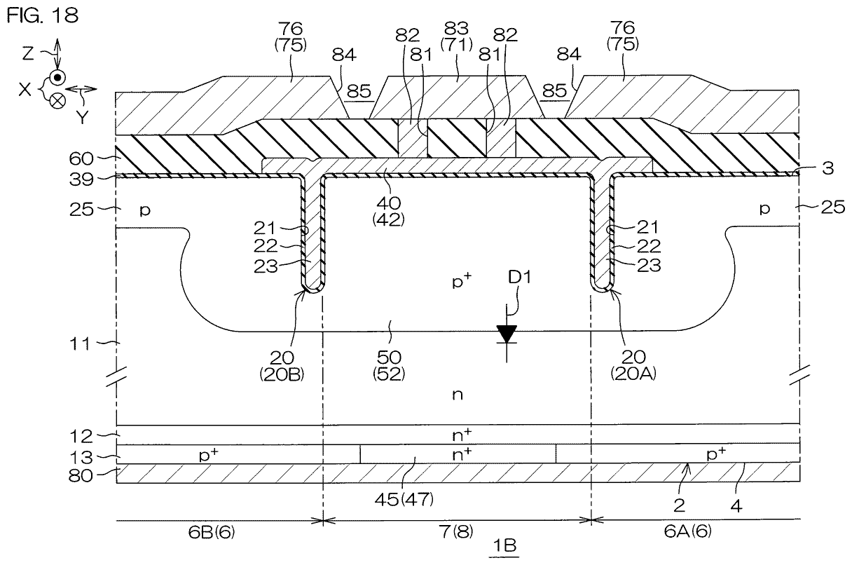

FIG. 15 is a plan view which shows a semiconductor device 1B according to the second embodiment. FIG. 16 is a plan view which shows a layout of the plurality of IGBT regions 6, the boundary region 7, the gate electrode 71 and the emitter electrode 75. FIG. 17 is an enlarged plan view which shows a layout of the plurality of IGBT regions 6 and the boundary region 7. FIG. 18 is a cross-sectional view taken along line XVIII-XVIII shown in FIG. 17.

With reference to FIG. 15 to FIG. 18, in this embodiment, the interlayer insulation film 60 includes at least one (in this embodiment, two) boundary gate opening 81 which exposes the boundary wiring 42 of the gate wiring 40. The number of the boundary gate openings 81 is arbitrary. Therefore, the interlayer insulation film 60 may include the single boundary gate opening 81.

In this embodiment, the plurality of boundary gate openings 81 are each formed in a band shape extending in the first direction X and formed at an interval in the second direction Y. A planar shape of the boundary gate opening 81 is arbitrary. The boundary gate opening 81 may be formed in a circular shape, an elliptical shape, a quadrangular shape or a polygonal shape in a plan view. Also, the plurality of boundary gate openings 81 may be arrayed at an interval in the first direction X.

The semiconductor device 1B includes a plurality of gate via electrodes 82 which are buried in the plurality of boundary gate openings 81 so as to be mechanically and electrically connected to the boundary wiring 42. Each of the gate via electrodes 82 may include at least one among a Ti-based metal film, a W-based metal film, an Al-based metal film and a Cu-based metal film.

As with the via electrode 70, the gate via electrode 82 may each have a laminated structure which includes a Ti-based metal film and a W-based metal film. The plurality of gate via electrodes 82 preferably face the gate wiring 40 (boundary wiring 42), the boundary cathode region 45 (second cathode region 47) and the boundary well region 50 (second well region 52) in the thickness direction of the chip 2.

In this embodiment, the gate electrode 71 includes a boundary gate finger electrode 83 which is led out directly above the boundary wiring 42 from the gate pad electrode 72. The boundary gate finger electrode 83 is formed in a band shape extending along the boundary wiring 42 so as to cover the plurality of gate via electrodes 82.

The boundary gate finger electrode 83 is electrically connected to the boundary wiring 42 via the plurality of gate via electrodes 82. That is, the boundary gate finger electrode 83 forms a current channel having a resistance value lower than that of the boundary wiring 42. The boundary gate finger electrode 83 faces the gate wiring 40 (boundary wiring 42), the boundary cathode region 45 (second cathode region 47) and the boundary well region 50 (second well region 52) in the thickness direction of the chip 2.

With regard to the second direction Y, the boundary gate finger electrode 83 has a width smaller than a width of the boundary well region 50 and has a peripheral edge that is positioned further on the boundary region 7 side than a peripheral edge of the boundary well region 50. Specifically, the boundary gate finger electrode 83 has a width smaller than a width of the boundary wiring 42 and has a peripheral edge that is positioned further on the boundary region 7 side than a peripheral edge of the boundary wiring 42.

In this embodiment, the boundary gate finger electrode 83 has a width smaller than a width of the boundary region 7 and has a peripheral edge which is positioned further inside than a peripheral edge of the boundary region 7. That is, the boundary gate finger electrode 83 is arranged only directly above the boundary region 7 in a plan view and not arranged above each of the IGBT regions 6.

The boundary gate finger electrode 83 is preferably arranged above the boundary region 7 at an interval from the plurality of trench structures 30 of the first IGBT region 6A and the plurality of trench structures 30 of the second IGBT region 6B in a plan view. The boundary gate finger electrode 83 is preferably arranged above the boundary region 7 at an interval from the first trench separation structure 20A and the second trench separation structure 20B in a plan view.

A width of the boundary gate finger electrode 83 may be substantially equal to the width of the boundary cathode region 45, may be larger than the width of the boundary cathode region 45 or may be smaller than the width of the boundary cathode region 45. A mode with no gate via electrode 82 described above may be adopted. In this case, the boundary gate finger electrode 83 enters into the boundary gate opening 81 from above the interlayer insulation film 60 and is mechanically and electrically connected to the boundary wiring 42.

In this embodiment, the emitter electrode 75 has a notched portion 84 which extends in a band shape along the boundary gate finger electrode 83 in a plan view. The notched portion 84 defines a slit 85 which extends in a band shape along the boundary gate finger electrode 83 together with the boundary gate finger electrode 83.

The slit 85 is formed directly above the boundary well region 50 in a plan view. It is preferable that the slit 85 is not positioned in a region out of the boundary well region 50 in a plan view. The slit 85 is preferably formed directly above the boundary region 7 in a plan view. It is particularly preferable that the slit 85 is not positioned in a region out of the boundary region 7 in a plan view.

In this embodiment, the slit 85 is formed above the boundary region 7 at an interval from the plurality of trench structures 30 of the first IGBT region 6A and the plurality of trench structure 30 of the second IGBT region 6B. Also, the slit 85 is formed above the boundary region 7 at an interval from the first trench separation structure 20A and the second trench separation structure 20B in a plan view. The slit 85 may face one of or both of the boundary cathode region 45 (second cathode region 47) and the boundary well region 50 (second well region 52) in the thickness direction of the chip 2.

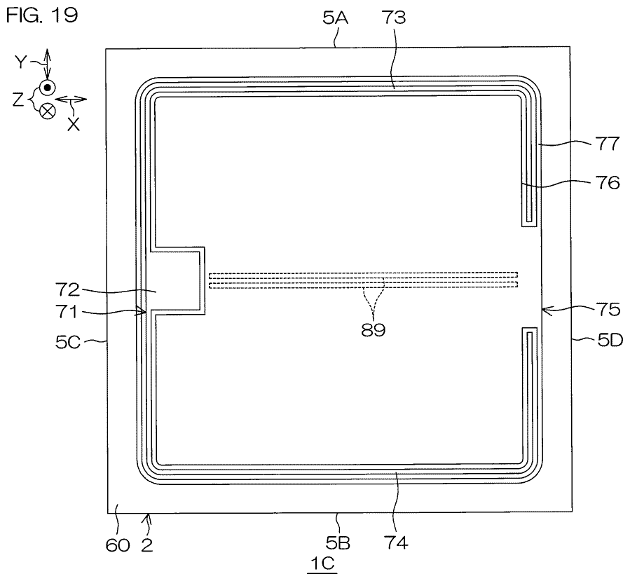

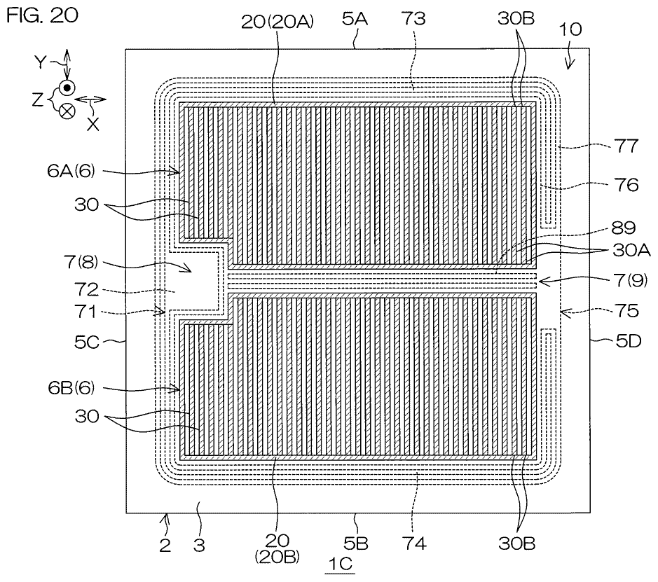

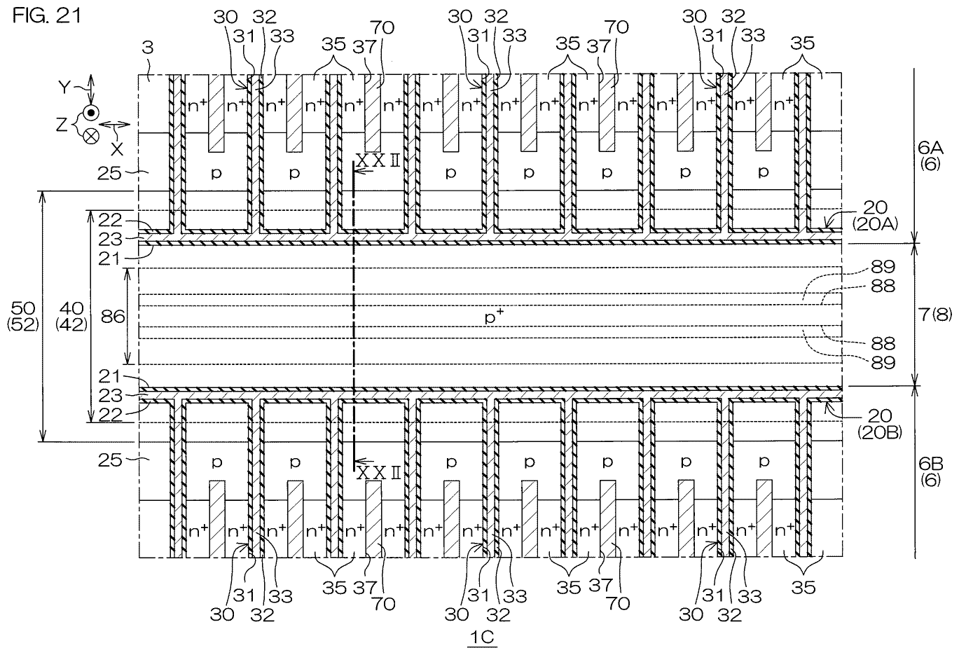

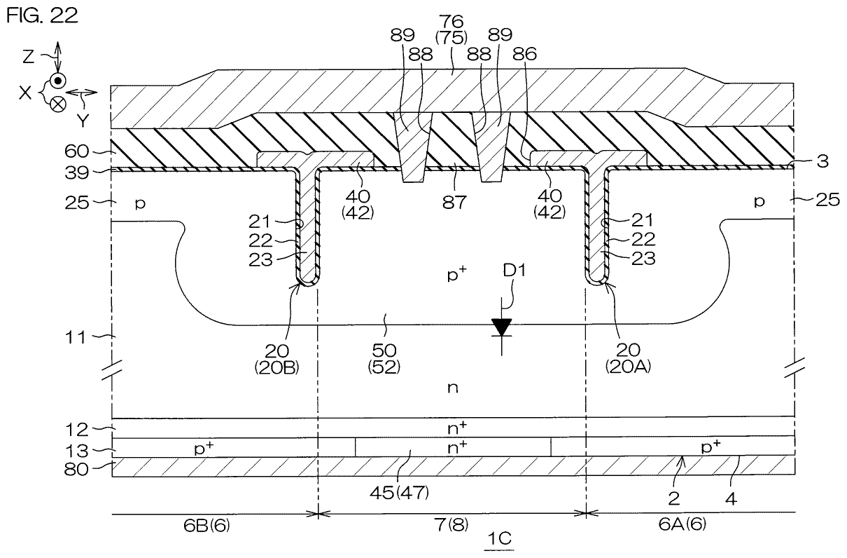

FIG. 19 is a plan view which shows a semiconductor device 1C according to the third embodiment. FIG. 20 is a plan view which shows a layout example of the plurality of IGBT regions 6, the boundary region 7, the gate electrode 71 and the emitter electrode 75. FIG. 21 is an enlarged plan view which shows a layout example of the plurality of IGBT regions 6 and the boundary region 7. FIG. 22 is a cross-sectional view taken along line XXII-XXII shown in FIG. 21.

With reference to FIG. 19 to FIG. 22, the gate wiring 40 has at least one (in this embodiment, one) opening portion 86 which is formed directly above the boundary region 7 so as to overlap the boundary well region 50 in the boundary wiring 42. The number of the opening portions 86 is arbitrary. The opening portion 86 may be referred to as a “removed portion” or a “divided portion.”

In this embodiment, the opening portion 86 is formed at an internal portion of the boundary wiring 42 at an interval from a peripheral edge of the boundary wiring 42 and exposes the main surface insulation film 39. As a matter of course, the opening portion 86 may be formed so as to penetrate through the peripheral edge of the boundary wiring 42. In this embodiment, the opening portion 86 is formed in a band shape extending along the boundary wiring 42 in a plan view.

The opening portion 86 is preferably not positioned in a region out of the boundary region 7 in a plan view. The opening portion 86 preferably has a width which is less than a width of the boundary region 7 in the second direction Y. That is, the opening portion 86 is preferably formed above the boundary region 7 at an interval from the plurality of trench structures 30 of the first IGBT region 6A and the plurality of trench structures 30 of the second IGBT region 6B. Also, the opening portion 86 is preferably formed above the boundary region 7 at an interval from the first trench separation structure 20A and the second trench separation structure 20B in a plan view.

In this embodiment, the boundary well region 50 is formed in the surface layer portion of the first main surface 3 so as to face the opening portion 86 in the thickness direction of the chip 2. The boundary well region 50 preferably faces an entire area of the opening portion 86. In this embodiment, the boundary cathode region 45 is formed in the surface layer portion of the second main surface 4 so as to face the opening portion 86 in the thickness direction of the chip 2. With regard to the second direction Y, a width of the boundary cathode region 45 may be not less than a width of the opening portion 86 or may be less than the width of the opening portion 86.

In this embodiment, the interlayer insulation film 60 has an opening covering portion 87 which is formed so as to enter into the opening portion 86 from above the boundary wiring 42 in the boundary region 7 and covers the opening portion 86. The opening covering portion 87 covers a side wall of the boundary wiring 42 and the main surface insulation film 39 inside the opening portion 86.

In this embodiment, the interlayer insulation film 60 includes at least one (in this embodiment, a plurality of) boundary contact opening 88 which exposes the boundary well region 50. The plurality of boundary contact openings 88 are formed in the opening covering portion 87 so as to pass through the inside of the opening portion 86. The plurality of boundary contact openings 88 may penetrate through the main surface insulation film 39 and further dig down from the first main surface 3 to the second main surface 4 side.

In this embodiment, the plurality of boundary contact openings 88 are each formed in a band shape extending in the first direction X inside the opening portion 86 and formed at an interval in the second direction Y. A planar shape of the boundary contact opening 88 is arbitrary. The boundary contact opening 88 may be formed in a circular shape, an elliptical shape, a quadrangular shape or a polygonal shape in a plan view. Also, the plurality of boundary contact openings 88 may be arrayed at an interval in the first direction X.

The semiconductor device 1C includes a plurality of boundary via electrodes 89 which are buried in the interlayer insulation film 60 so as to be electrically connected to the boundary well region 50. Each of the boundary via electrodes 89 may include at least one among a Ti-based metal film, a W-based metal film, an Al-based metal film and a Cu-based metal film. As with the via electrode 70, each of the boundary via electrodes 89 may have a laminated structure including a Ti-based metal film and a W-based metal film.

Specifically, the plurality of boundary via electrodes 89 are each buried in the plurality of boundary contact openings 88 at the opening covering portion 87. That is, the plurality of boundary via electrodes 89 are each formed in a band shape extending in the first direction X inside the opening portion 86 and formed at an interval in the second direction Y. As a matter of course, the plurality of boundary via electrodes 89 may be formed in a circular shape, an elliptical shape, a quadrangular shape or a polygonal shape in a plan view, depending on a layout of the boundary contact opening 88. Also, the plurality of boundary contact openings 88 may be arrayed at an interval in the first direction X.

The plurality of boundary via electrodes 89 pass through the opening portion 86 and face the gate wiring 40 (boundary wiring 42) across a part of the opening covering portion 87 (interlayer insulation film 60) in a plane direction of the first main surface 3. The plurality of boundary via electrodes 89 are mechanically and electrically connected to the boundary well region 50 inside the plurality of boundary contact openings 88. The plurality of boundary via electrodes 89 face the boundary cathode region 45 in the thickness direction of the chip 2.

In this embodiment, the emitter electrode 75 has a portion which covers the opening covering portion 87 (interlayer insulation film 60) so as to be electrically connected to the plurality of boundary via electrodes 89. Specifically, the emitter pad electrode 76 is mechanically and electrically connected to the plurality of boundary via electrodes 89 and electrically connected to the boundary well region 50 via the plurality of boundary via electrodes 89.

As described so far, the semiconductor device 1C includes the chip 2, the plurality of IGBT regions 6, the boundary region 7, the n-type boundary cathode region 45, the p-type boundary well region 50, the interlayer insulation film 60, the boundary via electrode 89 and the emitter electrode 75. The chip 2 has the first main surface 3 on one side and the second main surface 4 on the other side. The plurality of IGBT regions 6 are provided at an interval in the chip 2. The boundary region 7 is provided in a region between the plurality of IGBT regions 6 in the chip 2.

The boundary cathode region 45 is formed in the surface layer portion of the second main surface 4 in the boundary region 7. The boundary well region 50 is formed in the surface layer portion of the first main surface 3 in the boundary region 7. The boundary via electrode 89 is buried in the interlayer insulation film 60 so as to be electrically connected to the boundary well region 50. The emitter electrode 75 is arranged on the interlayer insulation film 60 such as to be electrically connected to the boundary via electrode 89.

According to this structure, the same effects as those of the semiconductor device 1A can be obtained. Also, according to the semiconductor device 1C, it is possible to form a current channel that connects the boundary cathode region 45 and the boundary via electrode 89 via the boundary well region 50 in the boundary region 7. Thereby, electrical characteristics of the boundary diode D1 can be made stable. Thus, it is possible to provide the semiconductor device 1C which contributes to an improvement in electrical characteristics.

The boundary well region 50 preferably has a portion which faces the boundary cathode region 45 in the thickness direction of the chip 2. The boundary via electrode 89 preferably faces the boundary cathode region 45 in the thickness direction of the chip 2. According to these structures, a current channel that connects the boundary cathode region 45 and the boundary via electrode 89 can be formed appropriately in the boundary region 7.

The semiconductor device 1C preferably includes the gate wiring 40 that is arranged above the first main surface 3 in the boundary region 7. In this case, the interlayer insulation film 60 preferably covers the gate wiring 40. Also, the boundary via electrode 89 is preferably buried in the interlayer insulation film 60 at an interval from the gate wiring 40.

The boundary well region 50 preferably has a portion which faces the gate wiring 40 in the thickness direction of the chip 2. The boundary cathode region 45 preferably has a portion which faces the gate wiring in the thickness direction of the chip. According to these structures, it is possible to form the boundary diode D1 stable in electrical characteristics in the boundary region 7 directly below the gate wiring 40.

The gate wiring 40 preferably has the opening portion 86 formed in a position where it overlaps the boundary region 7. In this case, the boundary well region 50 preferably has a portion that faces the opening portion 86 in the thickness direction of the chip 2. Also, the interlayer insulation film 60 preferably has the opening covering portion 87 which covers the opening portion 86. The boundary via electrode 89 is also preferably buried in the opening covering portion 87. According to this structure, it is possible to appropriately form a current channel which connects the boundary cathode region 45 and the boundary via electrode 89 in the boundary region 7 while securing functions of the gate wiring 40 in the boundary region 7.

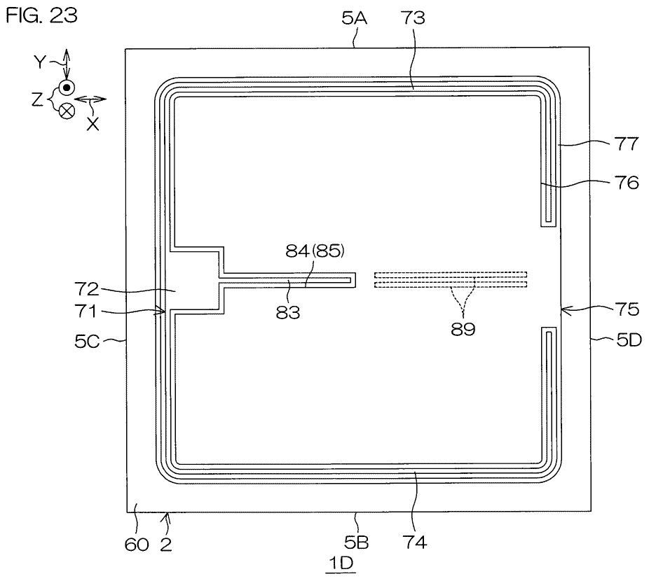

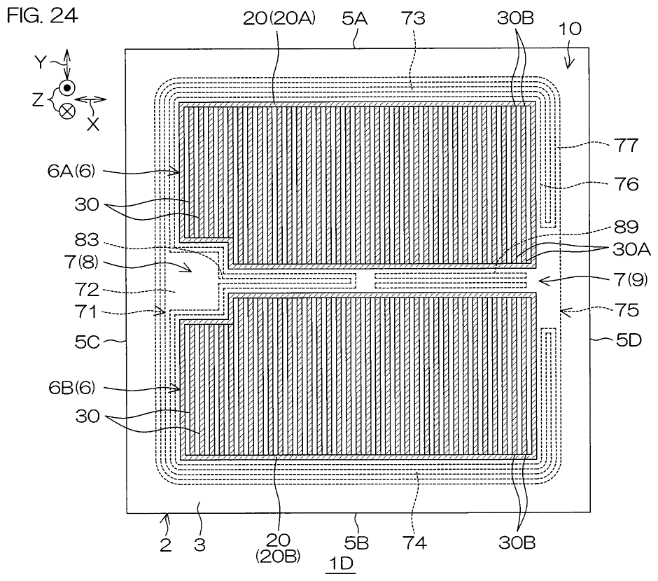

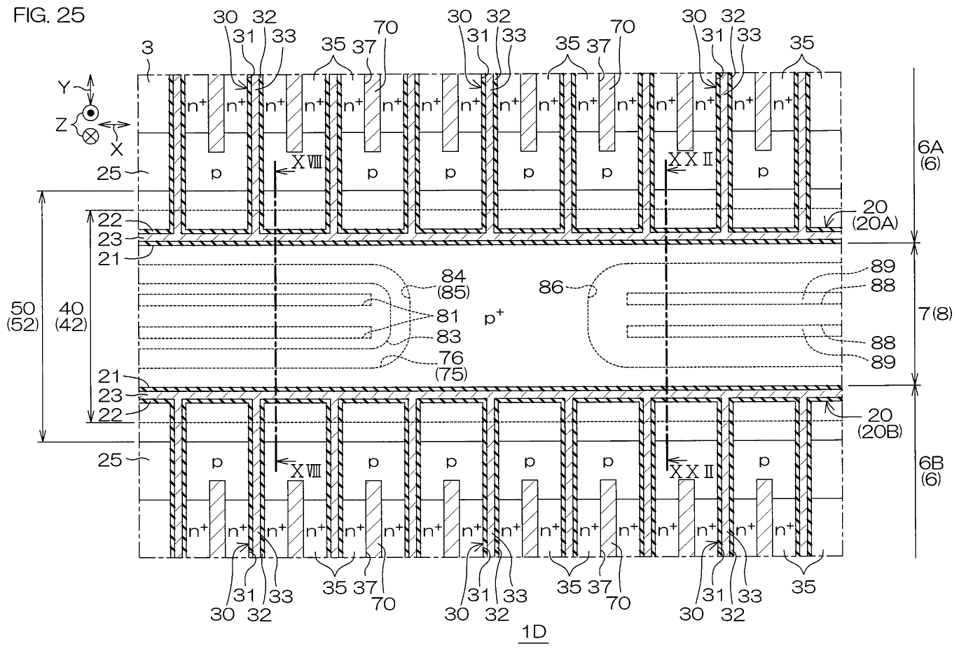

FIG. 23 is a plan view which shows a semiconductor device 1D according to the fourth embodiment. FIG. 24 is a plan view which shows a layout example of the plurality of IGBT regions 6, the boundary region 7, the gate electrode 71 and the emitter electrode 75. FIG. 25 is an enlarged plan view which shows a layout example of the plurality of IGBT regions 6 and the boundary region 7. A cross-sectional view taken along line XVIII-XVIII shown in FIG. 25 corresponds to FIG. 18 described above, and a cross-sectional view taken along line XXII-XXII shown in FIG. 25 corresponds to FIG. 22 described above.

With reference to FIG. 23 and FIG. 25, the semiconductor device 1D has both the features of the semiconductor device 1B according to the second embodiment and the features of the semiconductor device 1C according to the third embodiment. That is, as with the semiconductor device 1B according to the second embodiment, the semiconductor device 1D includes the boundary gate opening 81, the gate via electrode 82 buried in the boundary gate opening 81, the boundary gate finger electrode 83 electrically connected to the boundary wiring 42 via the gate via electrode 82 and the emitter electrode 75 (emitter pad electrode 76) having the notched portion 84 (slit 85).

Also, as with the semiconductor device 1C according to the third embodiment, the semiconductor device 1D includes the gate wiring 40 (boundary wiring 42) having the opening portion 86, the interlayer insulation film 60 having the opening covering portion 87 and the boundary contact opening 88, the boundary via electrode 89 buried in the boundary contact opening 88 and the emitter electrode 75 (emitter pad electrode 76) electrically connected to the boundary well region 50 via the boundary via electrode 89.

As shown in FIG. 23 to FIG. 25, the boundary gate finger electrode 83 is electrically connected to the boundary wiring 42 via the gate via electrode 82 in a region on the base end (pad wiring 41) side of the boundary wiring 42. On the other hand, the emitter electrode 75 is electrically connected to the boundary well region 50 via the boundary via electrode 89 in a region on the leading end side of the boundary wiring 42. As described so far, according to the semiconductor device 1D, the effects of the semiconductor device 1B and the effects of the semiconductor device 1C can be obtained.

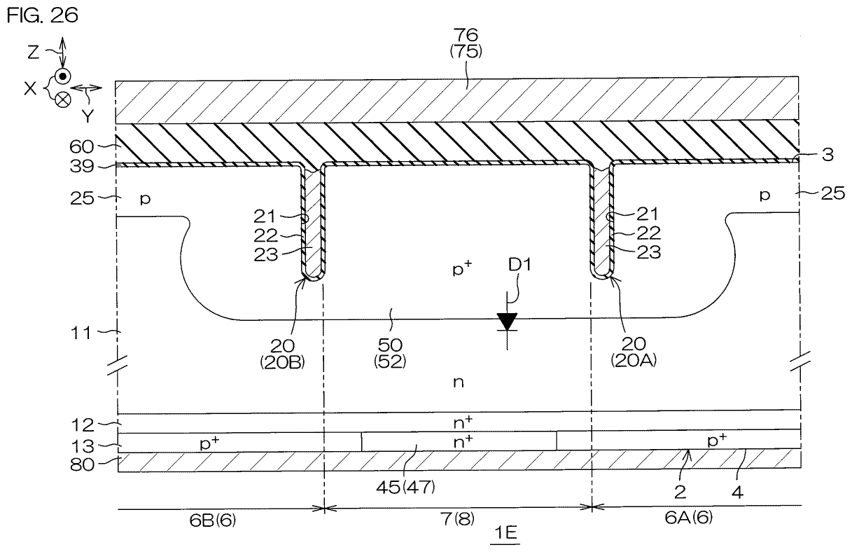

FIG. 26 corresponds to FIG. 6 and is a cross-sectional view which shows a semiconductor device 1E according to the fifth embodiment. With reference to FIG. 26, in this embodiment, the gate wiring 40 does not have the boundary wiring 42 but includes the pad wiring 41, the first outer wiring 43 and the second outer wiring 44. That is, the second cathode region 47 does not face the gate wiring 40 in the thickness direction of the chip 2. Also, the second well region 52 does not face the gate wiring 40 in the thickness direction of the chip 2. This structure is preferably applied to a case where the chip 2 relatively small in size and/or the trench structure 30 relatively small in gate resistance are adopted.

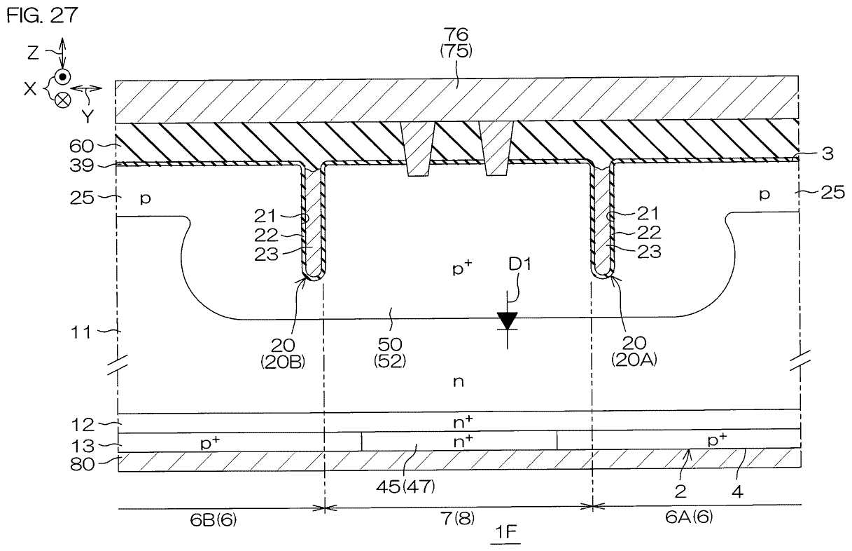

FIG. 27 corresponds to FIG. 6 and is a cross-sectional view which shows a semiconductor device 1F according to the sixth embodiment. With reference to FIG. 27, the semiconductor device 1F has a structure in which the boundary contact opening 88 and the boundary via electrode 89 according to the third embodiment are applied to the semiconductor device 1E according to the fifth embodiment. According to the semiconductor device 1F, the effects of the boundary via electrode 89 can be obtained in a structure in which no boundary wiring 42 is provided.

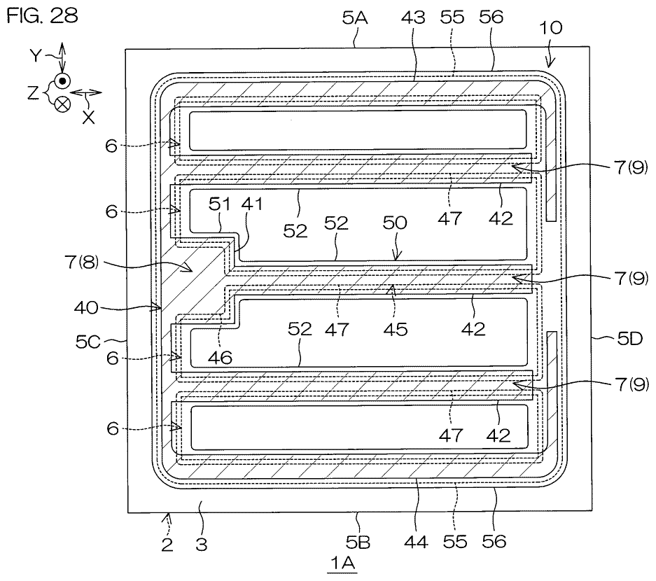

FIG. 28 is a plan view which shows a modified example that is to be applied to each of the embodiments described above. FIG. 28 shows an example in which the modified example is applied to the semiconductor device 1A according to the first embodiment. However, the modified example shown in FIG. 28 is also applicable to the above-described second to sixth embodiments. In each of the above-described embodiments, two IGBT regions 6 are shown.

However, as shown in FIG. 28, the n number (n≥3) of IGBT regions 6 may be provided at an interval. In this case, the n−1 number of the boundary regions 7 is provided in a region between two IGBT regions 6 which are adjacent to each other. In this case, at least one boundary region 7 may have the first region 8 and the second region 9, and all the boundary regions 7 are not necessarily provided with both of the first region 8 and the second region 9. Therefore, at least one boundary region 7 may have a fixed width (for example, only the second region 9). Structures in and out of each of the IGBT regions 6 and structures in and out of each of the boundary regions 7 are the same as each of the above-described embodiments.

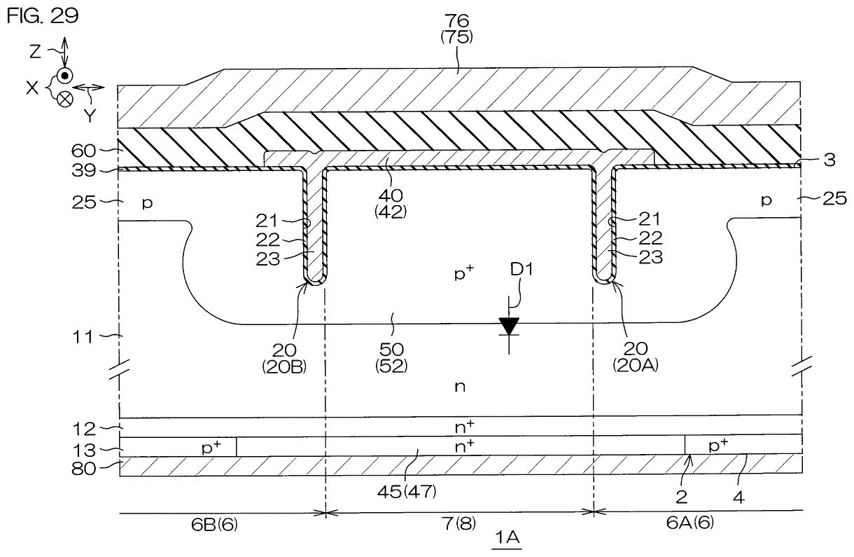

FIG. 29 is a plan view which shows a modified example to be applied to each of the above-described embodiments. FIG. 29 shows an example in which the modified example is applied to the semiconductor device 1A according to the first embodiment. However, the modified example shown in FIG. 29 is also applicable to the above-described second to sixth embodiments. In each of the above-described embodiments, there is shown an example in which the boundary cathode region 45 does not face the trench separation structure 20 in the thickness direction of the chip 2.

However, the boundary cathode region 45 may face the plurality of trench separation structures 20 in the thickness direction of the chip 2. As a matter of course, the boundary cathode region 45 may face the plurality of trench structures 30 in the thickness direction of the chip 2. That is, the boundary cathode region 45 may have a portion which is led out into each of the IGBT regions 6 from the boundary region 7.

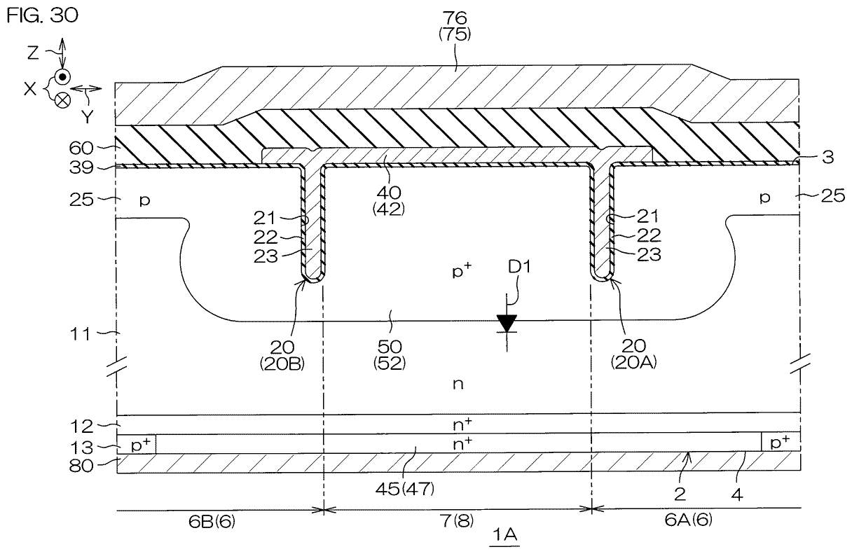

FIG. 30 is a plan view which shows a modified example applicable to each of the above-described embodiments. FIG. 30 shows an example in which the modified example is applied to the semiconductor device 1A according to the first embodiment. However, the modified example shown in FIG. 30 is also applicable to the above-described second to sixth embodiments.

In FIG. 29 described above, there is shown an example in which the boundary well region 50 is formed wider than the boundary cathode region 45 and faces the collector region 13 and the boundary cathode region 45 in the thickness direction of the chip 2. However, the boundary well region 50 may be formed narrower than the boundary cathode region 45 and may face only the boundary cathode region 45 in the thickness direction of the chip 2.

Each of the above-described embodiments can be further implemented by other embodiments. For example, in each of the above-described embodiments, there has been shown the example in which the chip 2 is made of a silicon monocrystal substrate. However, the chip 2 may be made of a SiC (silicon carbide) monocrystal substrate.

In each of the above-described embodiments, the n-type semiconductor region may be replaced by the p-type semiconductor region, and the p-type semiconductor region may be replaced by the n-type semiconductor region. In this case, a specific configuration is obtained by replacing an “n-type” with a “p-type” and also replacing a “p-type” with an “n-type” in the above-described descriptions and the attached drawings.

In each of the above-described embodiments, the first direction X and the second direction Y are regulated by a direction in which the first to fourth side surfaces 5A to 5D extend. However, the first direction X and the second direction Y may be an arbitrary direction as long as they can keep a relationship of intersecting each other (specifically, orthogonal to each other). For example, the first direction X may be a direction intersecting the first to fourth side surfaces 5A to 5D, and the second direction Y may be a direction intersecting the first to fourth side surfaces 5A to 5D.

Hereinafter, feature examples extracted from this specification and the drawings will be shown. Hereinafter, although alphanumeric characters within parentheses express corresponding constituents, etc. in the above-described embodiments, these are not meant to limit the scopes of respective Clauses to the embodiments. The “semiconductor device” according to the following Clauses may be replaced by a “semiconductor switching device” or a “RC-IGBT semiconductor device.”
[A1] A semiconductor device (1A to 1F) comprising: a chip (2) which has a first surface (3) on one side and a second surface (4) on the other side; IGBT regions (6) which are provided at an interval in the chip (2); a boundary region (7) which is provided in a region between the IGBT regions (6) in the chip (2); a first conductivity type (n-type) cathode region (45) which is formed in a surface layer portion of the second surface (4) in the boundary region (7); and a second conductivity type (p-type) well region (50) which is formed in a surface layer portion of the first surface (3) in the boundary region (7).
[A2] The semiconductor device (1A to 1F) according to A1, wherein a collector potential is to be applied to the cathode region (45), and an emitter potential is to be applied to the well region (50).
[A3] The semiconductor device (1A to 1F) according to A1 or A2, wherein the well region (50) has the portion which faces the cathode region (45) in a thickness direction of the chip (2).
[A4] The semiconductor device (1A to 1F) according to any one of A1 to A3, wherein the well region (50) is formed wider than the cathode region (45).
[A5] The semiconductor device (1A to 1F) according to any one of A1 to A4, further comprising: a second conductivity type (p-type) collector region (13) which is formed in the surface layer portion of the second surface (4) in the boundary region (7); wherein the well region (50) has a portion which faces the collector region (13) in a thickness direction of the chip (2).
[A6] The semiconductor device (1A to 1F) according to any one of A1 to A5, further comprising: a gate wiring (40, 42) which is arranged above the first surface (3) in the boundary region (7); wherein the cathode region (45) faces the gate wiring (40, 42) in a thickness direction of the chip (2), and the well region (50) faces the gate wiring (40, 42) in the thickness direction of the chip (2).
[A7] The semiconductor device (1A to 1F) according to A6, wherein the well region (50) is formed wider than the gate wiring (40, 42).
[A8] The semiconductor device (1A to 1F) according to A6 or A7, wherein the cathode region (45) is formed narrower than the gate wiring (40, 42).
[A9] The semiconductor device (1A to 1F) according to any one of A1 to A8, further comprising: a second conductivity type (p-type) base region (25) which is formed in the surface layer portion of the first surface (3) in each of the IGBT regions (6); wherein the well region (50) is formed deeper than the base region (25).
[A10] The semiconductor device (1A to 1F) according to A9, wherein the well region (50) is connected to the base region (25).
[A11] The semiconductor device (1A to 1F) according to A9 or A10, wherein the cathode region (45) does not face the base region (25) in a thickness direction of the chip (2).
[A12] The semiconductor device (1A to 1F) according to any one of A9 to A11, further comprising: a trench structure (30) which is formed through the base region (25) in the first surface (3) in each of the IGBT region (6) and to which a gate potential is to be applied; wherein the well region (50) is formed deeper than the trench structure (30) of each of the IGBT regions (6).
[A13] The semiconductor device (1A to 1F) according to A12, wherein the cathode region (45) does not face the trench structure (30) of each of the IGBT regions (6) in a thickness direction of the chip (2).
[A14] The semiconductor device (1A to 1F) according to A12 or A13, wherein the well region (50) is formed in the boundary region (7) so as to be in contact with the trench structure (30) of each of the IGBT regions (6).
[A15] The semiconductor device (1A to 1F) according to any one of A1 to A14, further comprising: an interlayer insulation film (60) which covers the first surface (3); and an emitter electrode (75) which is arranged on the interlayer insulation film (60) and electrically connected to the IGBT regions (6).
[A16] A semiconductor device (1A to 1F) comprising: a chip (2) which has a first surface (3) on one side and a second surface (4) on the other side; IGBT regions (6) which are provided at an interval in the chip (2); a boundary region (7) which is provided in a region between the IGBT regions (6) in the chip (2); a first conductivity type (n-type) cathode region (45) which is formed in a surface layer portion of the second surface (4) in the boundary region (7); a second conductivity type (p-type) well region (50) which is formed in a surface layer portion of the first surface (3) in the boundary region (7); an interlayer insulation film (60) which is formed on the first surface (3) in the boundary region (7); a via electrode (89) which is buried in the interlayer insulation film (60) so as to be electrically connected to the well region (50); and an emitter electrode (75) which is arranged on the interlayer insulation film (60) so as to be electrically connected to the via electrode (89).
[A17] The semiconductor device (1A to 1F) according to A16, wherein the well region (50) has a portion which faces the cathode region (45) in a thickness direction of the chip (2), and the via electrode (89) faces the cathode region (45) in the thickness direction of the chip (2).
[A18] The semiconductor device (1A to 1F) according to A16 or A17, further comprising: a gate wiring (40, 42) which is arranged above the first surface (3) in the boundary region (7); wherein the interlayer insulation film (60) covers the gate wiring (40, 42), and the via electrode (89) is buried in the interlayer insulation film (60) at an interval from the gate wiring (40, 42).
[A19] The semiconductor device (1A to 1F) according to A18, wherein the well region (50) has a portion which faces the gate wiring (40, 42) in a thickness direction of the chip (2), and the cathode region (45) has a portion which faces the gate wiring (40, 42) in the thickness direction of the chip (2).
[A20] The semiconductor device (1A to 1F) according to A18 or A19, wherein the gate wiring (40, 42) has an opening portion (86) which is formed at a position overlapping the boundary region (7), the well region (50) has a portion which faces the opening portion (86) in a thickness direction of the chip (2), the interlayer insulation film (60) has an opening covering portion (87) which covers the opening portion (86), and the via electrode (89) is buried in the opening covering portion (87).
[B1] A semiconductor device (1A to 1F) comprising: a chip (2) which has a first main surface (3) on one side and a second main surface (4) on the other side; IGBT regions (6, 6A, 6B) which are set at an interval in the first main surface (3); a boundary region (7) which is set between the IGBT regions (6, 6A, 6B) in the first main surface (3); an outer peripheral region (10) which is set around the IGBT regions (6, 6A, 6B) in the first main surface (3); an IGBT structure (TR1, TR2) which is formed in each of the IGBT regions (6, 6A, 6B); a boundary diode (D1) which is formed in the boundary region (7); and an outer diode (D2) which is formed in the outer peripheral region (10).
[B2] The semiconductor device (1A to 1F) according to B1, wherein the outer diode (D2) is connected to the boundary diode (D1) in parallel in a forward direction.
[B3] The semiconductor device (1A to 1F) according to B1 or B2, wherein the boundary diode (D1) is formed as a first reflux diode to the IGBT structure (TR1, TR2), and the outer diode (D2) is formed as a second reflux diode to the IGBT structure (TR1, TR2).
[B4] The semiconductor device (1A to 1F) according to any one of Bi to B3, wherein the boundary diode (D1) includes a boundary cathode region (45) which is formed in a surface layer portion of the second main surface (4) of the boundary region (7) and a boundary anode region (50) which is formed in a surface layer portion of the first main surface (3) of the boundary region (7), and the outer diode (D2) includes an outer cathode region (55) which is formed in the surface layer portion of the second main surface (4) of the outer peripheral region (10) and an outer anode region (56) which is formed in the surface layer portion of the first main surface (3) of the outer peripheral region (10).
[B5] The semiconductor device (1A to 1F) according to B4, wherein the boundary cathode region (45) is formed in the boundary region (7) at an interval from each of the IGBT regions (6, 6A, 6B) in a plan view.
[B6] The semiconductor device (1A to 1F) according to B4 or B5, wherein the boundary anode region (50) has a portion which faces the boundary cathode region (45) in a thickness direction of the chip (2).
[B7] The semiconductor device (1A to 1F) according to any one of B4 to B6, wherein the boundary anode region (50) is formed wider than the boundary cathode region (45).
[B8] The semiconductor device (1A to 1F) according to any one of B4 to B7, wherein the boundary region (7) is set in a band shape extending in one direction in a plan view, the boundary cathode region (45) is formed in a band shape extending in the one direction in a plan view, and the boundary anode region (50) is formed in a band shape extending in the one direction in a plan view.
[B9] The semiconductor device (1A to 1F) according to any one of B4 to B8, wherein the outer cathode region (55) is formed in the outer peripheral region (10) at an interval from each of the IGBT regions (6, 6A, 6B) in a plan view.
[B10] The semiconductor device (1A to 1F) according to any one of B4 to B9, wherein the outer anode region (56) has a portion which faces the outer cathode region (55) in a thickness direction of the chip (2).
[B11] The semiconductor device (1A to 1F) according to any one of B4 to B10, wherein the outer anode region (56) is formed wider than the outer cathode region (55).
[B12] The semiconductor device (1A to 1F) according to any one of B4 to Bli, wherein the outer cathode region (55) surrounds the IGBT regions (6, 6A, 6B) in a plan view, and the outer anode region (56) surrounds the IGBT regions (6, 6A, 6B) in a plan view.
[B13] The semiconductor device (1A to 1F) according to any one of B4 to B12, wherein the outer cathode region (55) is connected to the boundary cathode region (45)
[B14] The semiconductor device (1A to 1F) according to any one of B4 to B13, wherein the outer anode region (56) is connected to the outer anode region (56).
[B15] The semiconductor device (1A to 1F) according to any one of B1 to B14, further comprising: a collector region (13) which is formed in the surface layer portion of the second main surface (4) in each of the IGBT regions (6, 6A, 6B).
[B16] The semiconductor device (1A to 1F) according to B15, wherein the collector region (13) has a portion which is positioned at the surface layer portion of the second main surface (4) of the boundary region (7).
[B17] The semiconductor device (1A to 1F) according to B15 or B16, wherein the collector region (13) has a portion which is positioned at the surface layer portion of the second main surface (4) of the outer peripheral region (10).
[B18] The semiconductor device (1A to 1F) according to any one of B1 to B17, further comprising: trench separation structures (20, 20A, 20B) which are formed in the first main surface (3) so as to define the IGBT regions (6, 6A, 6B).
[B19] The semiconductor device (1A to 1F) according to any one of Bi to B18, further comprising: a boundary gate wiring (42) which is arranged above the first main surface (3) of the boundary region (7); wherein the boundary diode (D1) faces the boundary gate wiring (42) in a thickness direction of the chip (2).
[B20] The semiconductor device (1A to 1F) according to any one of B1 to B19, further comprising: an outer gate wiring (43, 44) which is arranged above the first main surface (3) of the outer peripheral region (10); wherein the outer diode (D2) faces the outer gate wiring (43, 44) in a thickness direction of the chip (2).

As described so far, although the embodiments have been described in detail, these are merely concrete examples used to clarify the technical contents of the present invention, the present invention should not be understood by being limited to these concrete examples, and the scope of the present invention is limited solely by the attached claims.

What is claimed is:

1. A semiconductor device comprising:
a chip which has a first surface on one side and a second surface on the other side;
IGBT regions which are provided in the chip at an interval;
a boundary region which is provided in a region between the IGBT regions in the chip;
a first conductivity type cathode region which is formed in a surface layer portion of the second surface in the boundary region; and
a second conductivity type well region which is formed in a surface layer portion of the first surface in the boundary region.

2. The semiconductor device according to claim 1,
wherein a collector potential is to be applied to the cathode region, and
an emitter potential is to be applied to the well region.

3. The semiconductor device according to claim 1,
wherein the well region has a portion which faces the cathode region in a thickness direction of the chip.

4. The semiconductor device according to claim 1,
wherein the well region is formed wider than the cathode region.

5. The semiconductor device according to claim 1, further comprising:
a second conductivity type collector region which is formed in the surface layer portion of the second surface in the boundary region;
wherein the well region has a portion which faces the collector region in a thickness direction of the chip.

6. The semiconductor device according to claim 1, further comprising:
a gate wiring which is arranged above the first surface in the boundary region;
wherein the cathode region faces the gate wiring in a thickness direction of the chip, and
the well region faces the gate wiring in the thickness direction of the chip.

7. The semiconductor device according to claim 6,
wherein the well region is formed wider than the gate wiring.

8. The semiconductor device according to claim 6,
wherein the cathode region is formed narrower than the gate wiring.

9. The semiconductor device according to claim 1, further comprising:
a second conductivity type base region which is formed in the surface layer portion of the first surface in each of the IGBT regions,
wherein the well region is formed deeper than the base region.

10. The semiconductor device according to claim 9,
wherein the well region is connected to the base region.

11. The semiconductor device according to claim 9,
wherein the cathode region does not face the base region in a thickness direction of the chip.

12. The semiconductor device according to claim 9, further comprising:
a trench structure which is formed through the base region in the first surface in each of the IGBT regions and to which a gate potential is to be applied;
wherein the well region is formed deeper than the trench structure of the each of the IGBT regions.

13. The semiconductor device according to claim 12,
wherein the cathode region does not face the trench structure of each of the IGBT regions in a thickness direction of the chip.

14. The semiconductor device according to claim 12,
wherein the well region is formed in the boundary region so as to be in contact with the trench structure of each of the IGBT regions.

15. The semiconductor device according to claim 1, further comprising:
an interlayer insulation film which covers the first surface; and
an emitter electrode which is arranged on the interlayer insulation film and electrically connected to the IGBT regions.

16. A semiconductor device comprising:
a chip which has a first surface on one side and a second surface on the other side;
IGBT regions which are provided at an interval in the chip;
a boundary region which is provided in a region between the IGBT regions in the chip;
a first conductivity type cathode region which is formed in a surface layer portion of the second surface in the boundary region;
a second conductivity type well region which is formed in a surface layer portion of the first surface in the boundary region;
an interlayer insulation film which is formed on the first surface in the boundary region;
a via electrode which is buried in the interlayer insulation film so as to be electrically connected to the well region; and
an emitter electrode which is arranged on the interlayer insulation film so as to be electrically connected to the via electrode.

17. The semiconductor device according to claim 16,
wherein the well region has a portion which faces the cathode region in a thickness direction of the chip, and
the via electrode faces the cathode region in the thickness direction of the chip.

18. The semiconductor device according to claim 16, further comprising:
a gate wiring which is arranged above the first surface in the boundary region;
wherein the interlayer insulation film covers the gate wiring, and
the via electrode is buried in the interlayer insulation film at an interval from the gate wiring.

19. The semiconductor device according to claim 18,
wherein the well region has a portion which faces the gate wiring in a thickness direction of the chip, and
the cathode region has a portion which faces the gate wiring in the thickness direction of the chip.

20. The semiconductor device according to claim 18,
wherein the gate wiring has an opening portion formed at a position overlapping the boundary region,
the well region has a portion which faces the opening portion in a thickness direction of the chip,
the interlayer insulation film has an opening covering portion which covers the opening portion, and
the via electrode is buried in the opening covering portion.
